(19) United States
(12) Patent Application Publication
(10) Pub. No.: US 2026/0005062 A1
(43) Pub. Date: Jan. 1, 2026

(54) THERMAL-PROCESS APPARATUSES AND METHODS TO REDUCE PROCESS-RELATED THERMAL SHRINKAGE

(71) Applicant: CANON KABUSHIKI KAISHA, Tokyo (JP)

(72) Inventors: Seth J. Bamesberger, Austin, TX (US); Alex Ruiz, Spicewood, TX (US); David Matthew Galvin, Austin, TX (US); William P. Morey, Round Rock, TX (US)

(21) Appl. No.: 18/756,710

(22) Filed: Jun. 27, 2024

(51) Int. Cl. H01L 21/687; H01L 21/324; H01L 21/67

(52) U.S. Cl. CPC H01L 21/68742; H01L 21/324; H01L 21/67103

(57) ABSTRACT

Some embodiments of a thermal module for baking a wafer in a low oxygen environment comprise a hot plate, a movable chamber lid having a recessed region defined by a chamber ceiling and a chamber sidewall for receiving a wafer, and lift pins for raising or lowering the wafer above or onto the hot plate. The recessed region is configured such that, when the wafer is positioned in the recessed region, a narrow gap is formed between the wafer and the recessed region such that a low oxygen environment between the chamber ceiling and a proximal surface of the wafer can be retained.

### BACKGROUND

Technical Field: This application generally concerns a thermal-process chamber that may be used in combination with imprint lithography and inkjet-based adaptive planarization.

Background: Many processes that are performed in semiconductor processing subject a semiconductor wafer or other such substrate to very high temperatures (e.g., high-temperature treatments, high-temperature processes). Heating to a high temperature is used in various processes to trigger physical reactions (e.g., chemical reactions) to improve the physical, optical, electrical, or chemical properties of the wafer in order to enhance the performance or quality of a resulting integrated circuit or semiconductor device, for example.

High-temperature processing may be required after or during processes for patterning, plasma etching, coating, cleaning, ion implantation, or the like. In a typical processing procedure, a wafer is transferred from a room temperature storage device by a robotic wafer handler into a processing or reaction chamber, where it is subjected to a high-temperature treatment or processing and is then transferred by the wafer handler from the high-temperature chamber to a chamber for cooling the wafer, or back to the same storage device or to a separate storage device for processed wafers.

### SUMMARY

Some embodiments of a thermal module for baking a wafer in a low oxygen environment comprise a hot plate, a movable chamber lid having a recessed region defined by a chamber ceiling and a chamber sidewall for receiving a wafer, and lift pins for raising or lowering the wafer above or onto the hot plate. The recessed region is configured such that, when the wafer is positioned in the recessed region, a narrow gap is formed between the wafer and the recessed region such that a low oxygen environment between the chamber ceiling and a proximal surface of the wafer can be retained.

Some embodiments of a thermal module for baking a wafer in a low oxygen environment comprise a hot plate, a movable chamber lid having a recessed region defined by a chamber ceiling and a chamber sidewall for receiving a wafer, lift pins for raising or lowering the wafer above or onto the hot plate, and a control device. The control device is configured to control the movable chamber lid and the lift pins to move in synchronization.

Some embodiments of a method comprise controlling lift pins to move a wafer from a first position to a second position, and controlling a movable chamber lid to move from a third position to a fourth position. The movable chamber lid has a recessed region defined by a chamber ceiling and a chamber sidewall for receiving the wafer. And the movable chamber lid and the lift pins are controlled to move in synchronization while the lift pins move the wafer from the first position to the second position and the movable chamber lid moves from the third position to the fourth position.

### BRIEF DESCRIPTION OF THE DRAWINGS

FIG. 1A is a schematic illustration of an example embodiment of a substrate-processing system.

FIG. 1B illustrates an example embodiment of a thermal-process chamber in an open position.

FIG. 2 illustrates an example embodiment of an upper member.

FIG. 3 illustrates sectional views of the upper member and the lower member when the thermal-process chamber is in an open position.

FIG. 4 illustrates sectional views of the upper member and the lower member when the thermal-process chamber is in a closed position.

FIGS. 5A, 5B, 6A, and 6B illustrate an example embodiment of an upper member and a substrate that are moved relative to a lower member while maintaining a micro environment between a processing surface of the substrate and a chamber ceiling of the upper member.

FIG. 7A illustrates sectional views of the upper member and the lower member when a thermal-process chamber is in a closed position.

FIG. 7B illustrates sectional views of the upper member and the lower member of an example embodiment of a thermal-process chamber.

FIG. 8 illustrates an example of a distance between a chamber ceiling of an upper member and a support surface of a lift pin.

FIG. 9 illustrates an example of a height difference between a processing surface of a substrate and an outer limit of a recessed region.

FIGS. 10A, 10B, 11A, and 11B illustrate an example embodiment of an upper member and a substrate that are moved relative to a lower member while maintaining a micro environment between a processing surface of the substrate and a chamber ceiling of the upper member.

FIG. 12A illustrates an example embodiment of an upper member.

FIG. 12B illustrates an example embodiment of an upper member.

FIG. 12C illustrates an example embodiment of an upper member.

FIG. 13 illustrates an example embodiment of an operational flow for processing a substrate.

FIG. 14 illustrates an example embodiment of an operational flow for processing a substrate.

FIG. 15 illustrates an example embodiment of an operational flow for processing a substrate.

FIG. 16 illustrates an example embodiment of an operational flow for processing a substrate.

FIG. 17 illustrates an example embodiment of an operational flow for processing a substrate.

FIG. 18 is a schematic illustration of an example embodiment of a control device.

FIG. 19 is a schematic illustration of an example embodiment of a thermal-process chamber.

FIG. 20 is a schematic illustration of an example embodiment of a substrate-processing system.

FIG. 21A illustrates an example of the air mass fraction across the surface of a substrate.

FIG. 21B illustrates an example of the air mass fraction across the surface of a substrate.

FIG. 22 is a graph that illustrates the air mass fractions across the surfaces of two substrates.

### DESCRIPTION

The following paragraphs describe certain explanatory embodiments. Other embodiments may include alternatives, equivalents, and modifications. Additionally, the explanatory embodiments may include several novel features, and a particular feature may not be essential to some embodiments of the devices, systems, and methods that are described herein. Furthermore, some embodiments include features from two or more of the following explanatory embodiments. Thus, features from various embodiments may be combined and substituted as appropriate.

Also, as used herein, the conjunction “or” generally refers to an inclusive “or,” although “or” may refer to an exclusive “or” if expressly indicated or if the context indicates that the “or” must be an exclusive “or.”

Moreover, as used herein, the terms “first,” “second,” “third,” and so on, do not necessarily denote any ordinal, sequential, or priority relation and may be used to more clearly distinguish one member, operation, element, group, collection, set, region, section, etc. from another without expressing any ordinal, sequential, or priority relation. Thus, a first member, operation, element, group, collection, set, region, section, etc. discussed below could be termed a second member, operation, element, group, collection, set, region, section, etc. without departing from the teachings herein.

And in the following description and in the drawings, like reference numbers designate identical or corresponding members throughout the several views.

Additionally, in this description and the drawings, an alphabetic suffix on a reference number may be used to indicate a specific instance of the feature identified by the reference number. For example, the robotic substrate handlers in a group of robotic substrate handlers may be identified with the reference number 90 when a specific robotic substrate handler is not being distinguished. However, 90A may be used to identify a specific robotic substrate handler when the specific robotic substrate handler is being distinguished from the rest of the robotic substrate handlers 90.

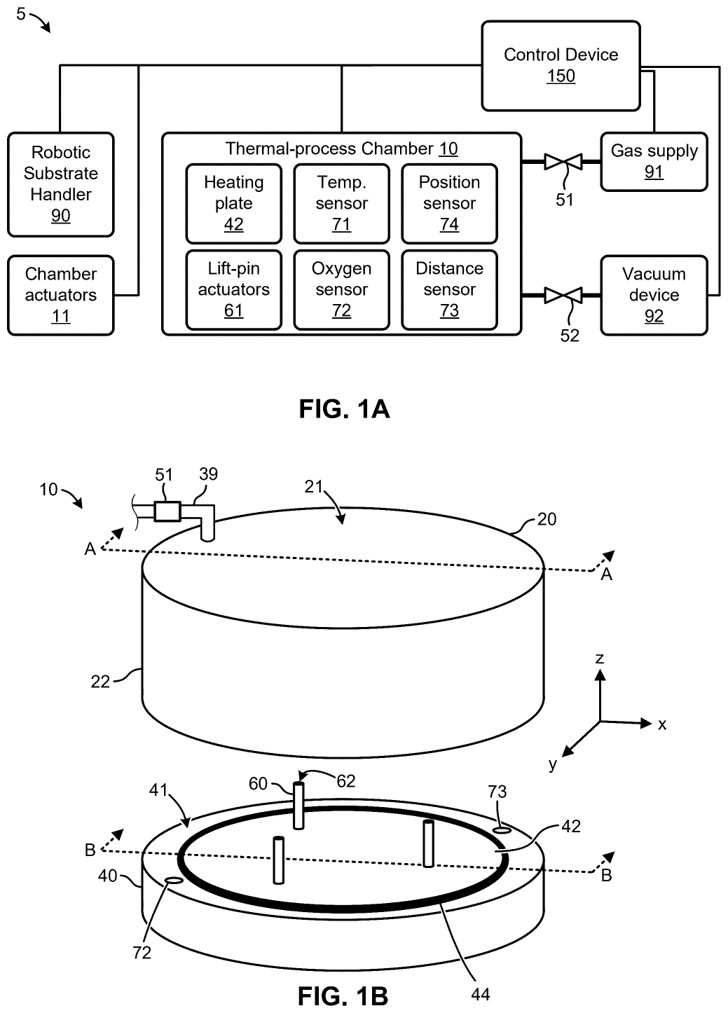

FIG. 1A is a schematic illustration of an example embodiment of a substrate-processing system 5. The substrate-processing system 5 includes a thermal-process chamber 10, chamber actuators 11, a control device 150, a robotic substrate handler 90, a gas supply 91, a vacuum device 92, a supply-side valve 51, and an exhaust-side valve 52.

The thermal-process chamber 10 (chamber 10) performs thermal processes (e.g., baking) on substrates (e.g., wafers). The thermal-process chamber 10 may be a baking machine or may be a thermal module of a baking machine, for example a combined baking-cooling machine. And a baking machine or a thermal module may include one or more of the following in addition to the thermal-process chamber 10: the control device 150, the chamber actuators 11, the robotic substrate handler 90, the gas supply 91, the vacuum device 92, the supply-side valve 51, and the exhaust-side valve 52.

The chamber actuators 11 can open and close the thermal-process chamber 10. The robotic substrate handler 90 can place a substrate in the thermal-process chamber 10 or remove a substrate from the thermal-process chamber 10. The gas supply 91 can supply a purge gas to the thermal-process chamber 10. And the vacuum device 92 can remove gases from the thermal-process chamber 10 (e.g., by generating a negative pressure that draws gases from the thermal-process chamber 10).

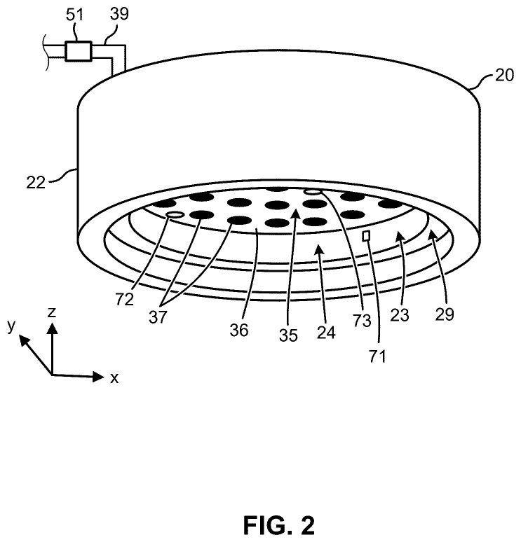

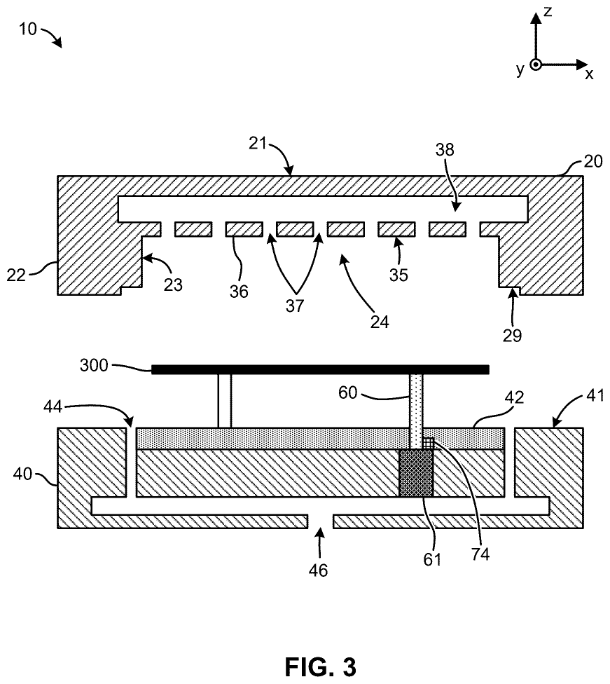

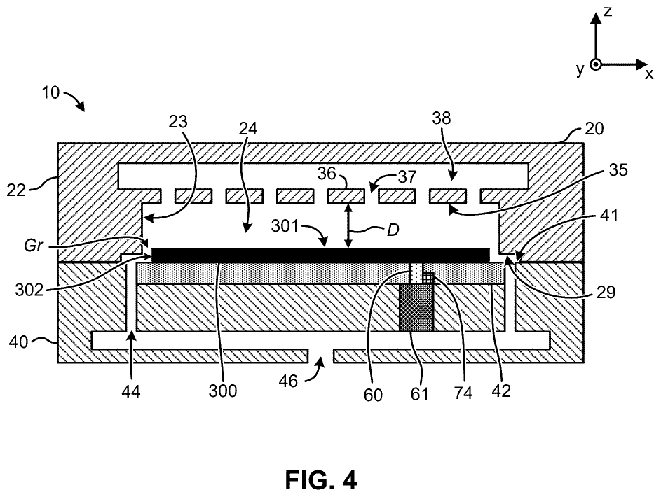

FIG. 1B illustrates an example embodiment of a thermal-process chamber 10 (chamber 10) in an open position. The chamber 10 includes an upper member 20 (a chamber lid) and a lower member 40 (a chamber base). FIG. 2 illustrates an example embodiment of the upper member 20. Also, FIG. 3 illustrates sectional views of the upper member 20 and the lower member 40 when the thermal-process chamber 10 is in an open position. And FIG. 4 illustrates sectional views of the upper member 20 and the lower member 40 when the thermal-process chamber 10 is in a closed position.

In FIG. 1B, the view of the chamber 10 is a perspective view. The view in FIG. 2 is a perspective view of the upper member 20 that looks upward along the z axis, showing the interior of the upper member 20. And the sectional views of the upper member 20 that are shown herein, including the sectional views in FIGS. 3 and 4, are taken along the plane that is indicated by the line A-A in FIG. 1B, and the sectional views of the lower member 40 that are shown herein, including the sectional views in FIGS. 3 and 4, are taken along the plane that is indicated by the line B-B in FIG. 1B.

The chamber actuators 11 can move one or more of the upper member 20 and the lower member 40 along the z-axis, and therefore can open and close the chamber 10.

The chamber 10 can perform one or more processes on a substrate (e.g., wafer) while the substrate is in the chamber 10. Examples of processes include baking processes or other high-temperature processes under controlled atmospheres.

The upper member 20 (the chamber lid) includes one or more walls 22, a recessed region 24 (also referred to as a recessed portion), one or more plateaus 29 that surround the recessed region 24, a chamber ceiling 35, a gas-flow distributor 36 (distributor 36), a distribution chamber 38, and an inlet port 39. The recessed region 24 is three-dimensional space that is defined by the chamber ceiling 35 and by one or more chamber sidewalls 23 (inner surfaces). Also, some embodiments do not include the plateau 29.

The one or more walls 22 extend downward from the periphery of the upper surface 21 of the upper member 20. For example, if the shape of the upper member 20 on the x-y plane is a circle or an oval (e.g., as shown in FIGS. 1B and 2), then the upper member 20 may have one wall 22 that circumscribes the outer edge of the upper surface 21. Also for example, if the shape of the upper member 20 on the x-y plane is a quadrilateral, then the upper member 20 may have four walls 22 that collectively circumscribe the outer edge of the upper surface 21. A wall 22 of the upper member 20 may also be referred to herein as an “upper wall 22.” The shape of the recessed region 24 in the x-y plane, which is defined by the one or more chamber sidewalls 23, matches the shape of the substrate 300.

The inlet port 39 can receive a flow of a purge gas from the gas supply 91. The gas-flow distributor 36 (e.g., shower head, gas distribution plate, diffusion board, discharge nozzle, perforated diffusion plate) is located in the chamber ceiling 35 in this embodiment. And, in this embodiment, the distributor 36 includes a plurality of openings 37. Gas that flows through the inlet port 39 enters the distribution chamber 38 and flows through the openings 37 of the distributor 36 into the recessed region 24. The distributor 36 may cause the gas to uniformly flow to the different areas (e.g., a central area, an area that is closer to the chamber sidewall 23) of the recessed region 24. Also, the flow of the purge gas into the upper member 20 can be controlled (e.g., stopped, started) by a supply-side valve 51.

The lower member 40 includes a floor 41, a heating plate 42, at least one vent 44, a gas outlet 46, lift pins 60, and lift-pin actuators 61. When activated, the heating plate 42 emits heat, and, to heat the interior of the chamber 10, the heating plate 42 can be controlled to heat to a specific temperature based on a temperature sensor attached to the heating plate 42. In some embodiments, the heating plate 42 is controlled according to a detected temperature of one or more of the following: the heating plate 42, the interior of the chamber 10 (e.g., the recessed portion 24), the substrate 300, and a processing surface 301 of the substrate 300.

The at least one vent 44 can be an annular opening adjacent to the heating plate 42 that has an annular connection to an annular vacuum chamber that supplies a uniform pressure drop around the heating plate 42. The vent 44 may be an opening in the floor 41 adjacent the heating plate 42, and the vent 44 allows gases to travel through the floor 41. In some embodiments, the heating plate 42 also includes one or more vents therethrough. Gas that flows into the at least one vent 44 exits through the gas outlet 46, which can be connected to the vacuum device 92. Also, for example, the gas outlet 46 may be attached to the exhaust-side valve 52. Additionally, the vacuum device 92 may be a vacuum chamber, a fan, a region that has less pressure than the thermal-process chamber 10, or another device that can draw gas into the at least one vent 44.

The lift pins 60 can hold a substrate 300. In this embodiment, the lower member 40 includes a respective lift-pin actuator 61 for each of the lift pins 60, and each lift-pin actuator 61 can raise and lower a respective lift pin 60. In some embodiments, a lift-pin actuator 61 can raise or lower two or more lift pins 60. By raising or lowering the lift pins 60, the lift-pin actuators 61 can cause the lifts pins 60 to raise or lower a substrate 300 that is held by the lift pins 60. Accordingly, the lifts pins 60 and the lift-pin actuators 61 can operate together to raise or lower the substrate 300 that is held by the lift pins 60.

The upper member 20 can be separated from the lower member 40 (e.g., by raising the upper member 20, by lowering the lower member 40), which allows a substrate 300 to be placed on the support surfaces 62 of the lift pins 60 or removed from the support surfaces 62 of the lift pins 60.

Also, the chamber 10 may include one or more sensors. Examples of sensors include the following: temperature sensors 71, oxygen sensors 72, distance sensors 73, and position sensors 74. For example, distance sensors 73 may detect the distance between the chamber ceiling 35 and the substrate 300 or the distance between the upper member 20 and the lower member 40. Also for example, position sensors 74 may detect the positions of the lift pins 60. And the sensors (e.g., temperature sensors 71, oxygen sensors 72, distance sensors 73, and position sensors 74) communicate with (e.g., send information to) the control device 150.

The control device 150 controls the heating plate 42 and the lift-pin actuators 61. Also, the control device 150 receives information (e.g., sensor measurements) from the sensors (e.g., temperature sensors 71, oxygen sensors 72, distance sensors 73, and position sensors 74).

As shown in FIG. 4, when the thermal-process chamber 10 is in a closed position, the wall 22 (or walls 22) of the upper member 20 are in contact with, or close to, the floor 41 of the lower member 40. At least part of the substrate 300 is positioned within the recessed region 24. And there is a gap of distance D between the chamber ceiling 35 of the upper member 20 and the substrate 300. Also, the lift pins 60 have been lowered such that the substrate 300 is in contact with, or close to, the heating plate 42. The heating plate 42 may include a plurality of support pads or a platen on which the substrate 300 rests when it is in contact with the heating plate 42.

During the overall processing of the substrate 300 (e.g., before the substrate 300 is placed in the chamber 10), a processing surface 301 (proximal surface, top surface) of the substrate 300, which is proximal to the chamber ceiling 35, may be subjected to one or more processes, such as patterning, plasma etching, coating, cleaning, curing, oxidation, layer formation, deposition, doping, planarization, etching, formable-material removal, and ion implantation.

And during the processing of the substrate 300 by the chamber 10, the chamber 10 heats the substrate 300 (e.g., the processing surface 301) to a specified temperature for a specified duration. Once the duration ends, the chamber 10 opens, which begins the cooling of the substrate 300. Once the temperature of the substrate 300 has decreased sufficiently (e.g., once the temperature has reached or fallen below a threshold), the substrate 300 can be removed from the chamber 10, for example by the robotic substrate handler 90.

Furthermore, to minimize thermal shrinkage of the substrate 300 in general, or of the processing surface 301 in particular, the concentration of oxygen in the environment in the chamber 10 may be reduced to a specified level (e.g., 10,000 ppm, 2000 ppm, 1500 ppm, 1000 ppm, 500 ppm, 100 ppm, 1 ppm, 0.05 ppm) before the temperature of the substrate 300 (or the processing surface 301 in particular) reaches a first specified temperature, and the concentration of oxygen may be maintained below the specified level (e.g., 2000 ppm, 1500 ppm, 1000 ppm, 500 ppm, or 100 ppm) until the temperature of the substrate 300 (or the processing surface 301 in particular) has cooled below a second specified temperature, which may or may not be identical to the first temperature. For example, in some embodiments, to minimize post-bake thermal shrinkage, the temperature of the substrate 300 does not exceed 125° C. before the concentration of oxygen in the environment in the chamber 10 near the processing surface 301 is less than 1000 ppm. And, in some embodiments, the concentration of oxygen in the environment in the chamber 10 near the processing surface 301 is maintained to be less than 1000 ppm until the temperature of the substrate 300 drops below 250° C.

To reduce the concentration of oxygen near the substrate 300 (and near the processing surface 301, specifically), purge gas (for example nitrogen, a noble gas, or any gas that does not substantially react with the processing surface 301 at elevated temperatures that are experienced within the thermal-process chamber 10) is supplied through the inlet port 39. In this description, purge gas refers to gas that contains no oxygen or only a small amount of oxygen (e.g., an amount that is less than a specified limit). For example, some embodiments use nitrogen (N₂) as a purge gas. The purge gas enters the distribution chamber 38 and then flows through the openings 37 in the distributor 60 to the recessed region 24. Also, the gas in the chamber 10, which may include purge gas, may be drawn through the vent 44 in the lower member 40 and expelled from the chamber 10. Thus, the gas that is in the chamber 10 before the purge gas is supplied can be replaced with the purge gas, which lowers the oxygen concentration in the chamber 10.

However, reducing the oxygen concentration in the chamber 10 (e.g., near the processing surface 301 of the substrate 300) requires time. Additionally, once the substrate 300 is placed on the lift pins 60 by the robotic substrate handler 90, the substrate 300 will be in proximity to the heating plate 42 and the temperature of the substrate 300 will start increasing. Waiting for the oxygen concentration to be sufficiently reduced before heating the substrate 300 above a temperature threshold increases the processing time. And maintaining a low oxygen concentration while the substrate 300 is cooled may increase the cooling time because the gas in the chamber 10 (which may be mostly or entirely purge gas) is heated with the substrate 300 by the heating plate 42. Opening the chamber 10 by raising upper member while also raising the lift pins 60 can allow a cooler gas to circulate between the substrate 300 and heating plate 42. However, opening the chamber 10 to enable cooler air to enter the chamber 10 and cool the substrate 300 may also increase the oxygen concentration to a concentration at the processing surface 301 that is too high.

Also, a manufacturer of an integrated circuit or semiconductor device usually attempts to minimize processing times in order to maximize throughput. If the time required to heat and then cool the substrate 300 is longer, the total cycle time for each substrate 300 is longer, which increases the cost of each substrate 300. Thus, reducing the time required to heat and then cool the substrate 300 may be advantageous.

The recessed region 24 is sized such that the recessed region 24 has dimensions in the x-y plane that are only slightly larger (for example, 0.1 mm to 3 mm, or 0.1% to 1% of the diameter or width) than the dimensions of the substrate 300 in the x-y plane. Thus, when at least part of the substrate 300 is positioned in the recessed region 24, a narrow gap Gr exists between an outer edge 302 (e.g., radial edge) of the substrate 300 and the chamber sidewalls 23 of the upper member 20. In some embodiments, for example the embodiment in FIG. 4, the narrow gap Gris in a radial direction from a center of the substrate 300. This decreases or limits the flow of the purge gas through the gap Gr, which reduces or limits the flow of the purge gas away from the processing surface 301 and retains or traps more of the purge gas in the recessed region 24. And this also decreases, limits, or eliminates the flow of gas outside of the recessed region 24 into the recessed region 24, including the space between the substrate 300 and the chamber ceiling 35. Accordingly, a micro environment may be established in the recessed region 24, between the processing surface 301 and the chamber ceiling 35. And reducing the oxygen concentration in the micro environment between the processing surface 301 and the chamber ceiling 35, which has a smaller volume than the volume of the entirety of the interior of the chamber 10, may be performed more quickly than reducing the oxygen concentration in the entirety of the interior of the chamber 10 because less purge gas is required to reduce the oxygen concentration in the micro environment. Thus, the recessed region 24 can reduce the time required to lower the oxygen concentration near the processing surface 301 of the substrate 300.

Also, the micro environment between the processing surface 301 and the chamber ceiling 35 may be maintained while the upper member 20 and the substrate 300 are moving relative to the lower member 40.

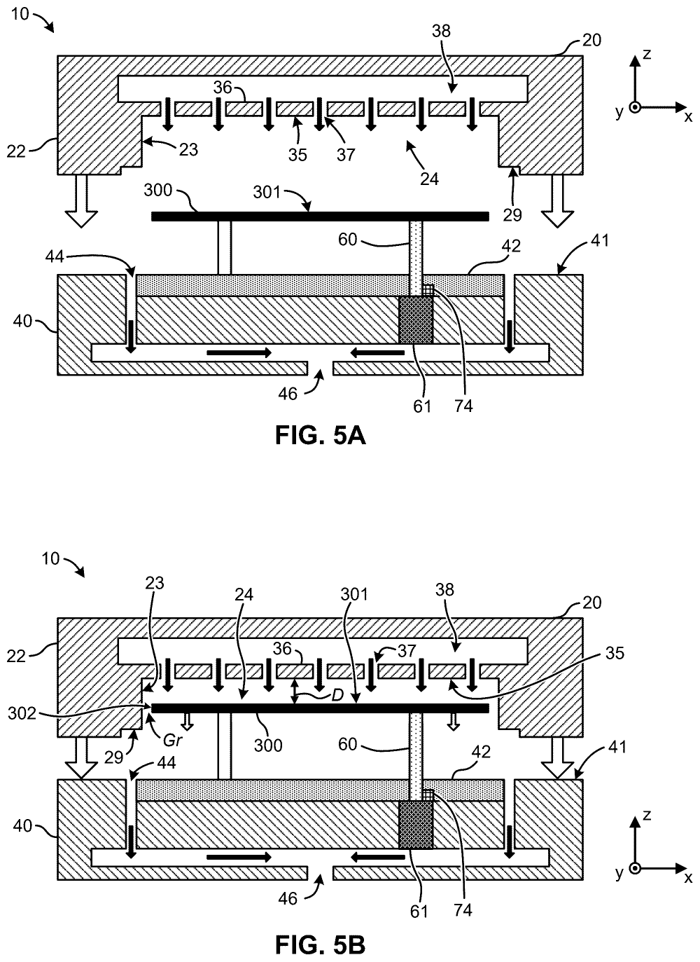

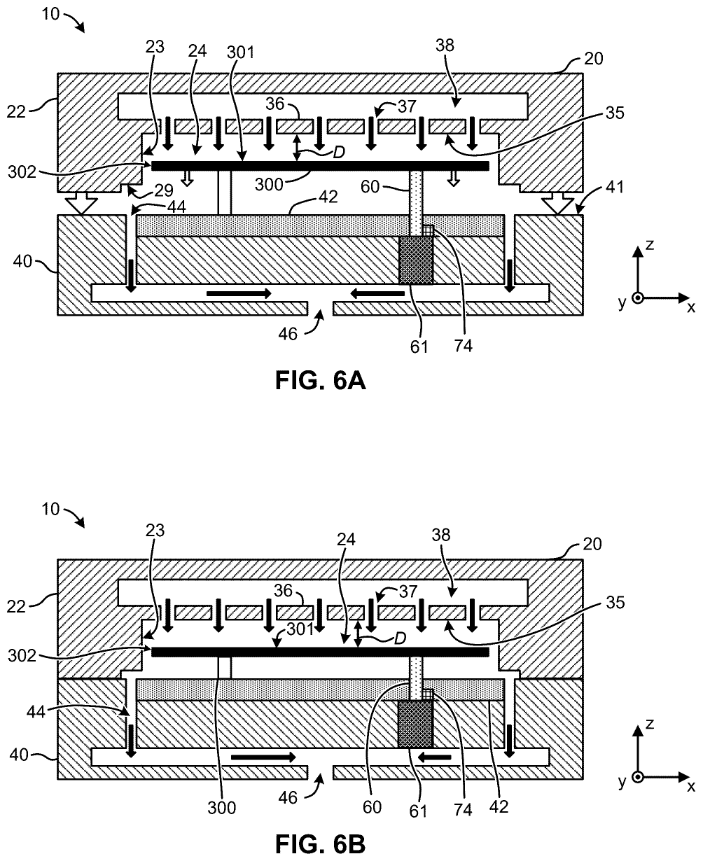

For example, FIGS. 5A, 5B, 6A, and 6B illustrate an example embodiment of an upper member 20 and a substrate 300 that are moved relative to a lower member while maintaining a micro environment between the processing surface 301 and the chamber ceiling 35.

Initially, as shown in FIG. 5A, a substrate 300 is placed on the support surfaces 62 of the lift pins 60 in the open chamber 10. The lift-pin actuators 61 have raised the lift pins 60 such that the substrate 300 is held away from the heating plate 42. The upper member 20 is positioned away from the lower member 40 such that none of the substrate 300 is positioned in the recessed region 24. The upper member 20 is moving toward the lower member 40, and purge gas is flowing through the openings 37, as indicated by the arrows through the openings 37. Also, any gas in the chamber 10 may be drawn in to the vent 44.

In FIG. 5B, the upper member 20 has been moved closer to the lower member 40 such that at least part of the substrate 300 is positioned in the recessed region 24. The outer edge 302 of the substrate 300 and the chamber sidewalls 23 of the upper member 20 form the narrow gap Gr therebetween. The lift-pin actuators 61 move the lift pins 60 to lower the substrate 300 in synchronization with the movement of the upper member 20 such that the distance D between the chamber ceiling 35 of the upper member 20 and the processing surface 301 of the substrate 300 does not change or is maintained within a specific, narrow range. Any gas in the chamber 10 may be drawn in to the vent 44. And the purge gas continues flowing through the openings 37, as indicated by the arrows through the openings 37 and out the vent 44. The flow of the purge gas lowers the concentration of oxygen in the micro environment between the chamber ceiling 35 of the upper member 20 and the processing surface 301 of the substrate 300. Thus, while the upper member 20 and the substrate 300 are moving, the purge gas lowers the concentration of oxygen in the micro environment near the processing surface 301.

In FIG. 6A, the upper member 20 and the substrate 300 are closer to the lower member 40. At least part of the substrate 300 is still positioned in the recessed region 24, and the distance D between the chamber ceiling 35 of the upper member 20 and the processing surface 301 of the substrate 300 has not changed. And the purge gas continues flowing through the openings 37 and out the vent 44. Therefore, the purge gas continues to lower the concentration of oxygen in the micro environment between the substrate 300 and the chamber ceiling 35 as the upper member 20 and the substrate 300 continue to move toward the lower member 40.

In FIG. 6B, the upper member 20 is in contact with the lower member 40. And the substrate 300 has stopped moving. In some embodiments, this is the closed position of the chamber 10. Also, the purge gas continues flowing through the openings 37 and out the vent 44. In some embodiments, when the chamber 10 is in the closed position, the upper member 20 is not in contact with the lower member, but a small gap is maintained between the upper member 20 and the lower member 40 so as restrict the flow gas in and out of the chamber 10 and prevent the generation of particles due to contact.

Consequently, as shown in FIGS. 5A, 5B, 6A, and 6B, the oxygen concentration near the processing surface 301 of the substrate 300 is lowered while the upper member 20 and the substrate 300 move toward the lower member 40. Accordingly, once the chamber 10 is in the closed position, the time required to lower the oxygen concentration near the processing surface 301 is reduced or eliminated, which allows the substrate 300 to be heated more quickly while still preventing or reducing thermal shrinkage.

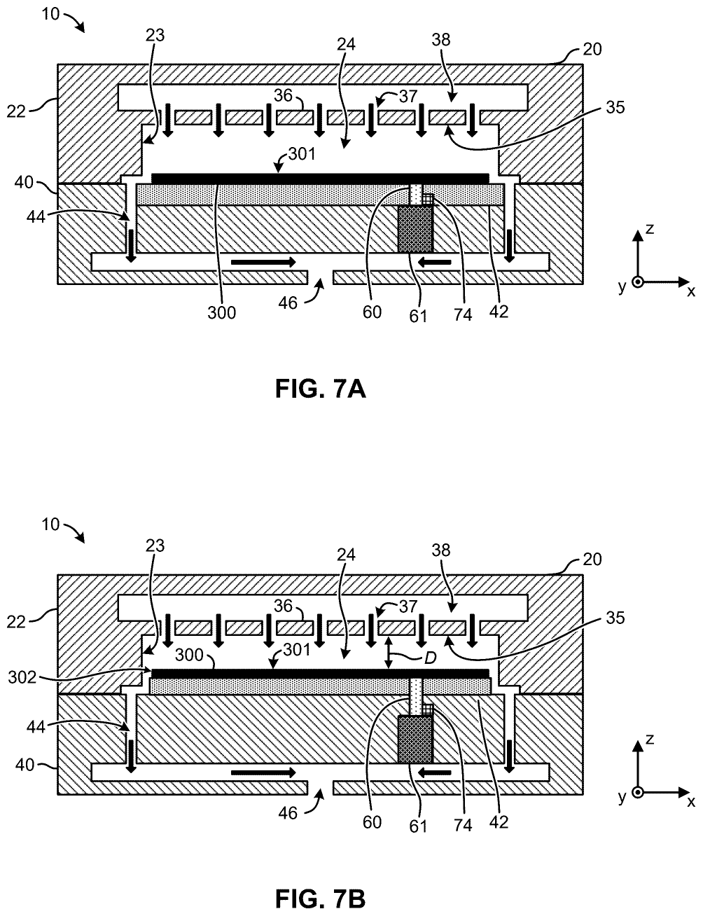

Additionally, the distance D between the chamber ceiling 35 of the upper member 20 and the processing surface 301 of the substrate 300 does not change in FIGS. 5B, 6A, and 6B. Thus, in some embodiments, the distance D between the chamber ceiling 35 of the upper member 20 and the processing surface 301 of the substrate 300 does not change even after the chamber is closed 10. However, in some embodiments, the lift pins 60 lower the substrate 300 closer to the heating plate 42 after the chamber 10 is in the closed position, for example as illustrated in FIG. 7A.

FIG. 7B illustrates sectional views of the upper member and the lower member of an example embodiment of a thermal-process chamber 10. In FIG. 7B, even when the substrate 300 has been lowered until it contacts the heating plate 42, the entire substrate 300 is positioned in the recessed region 24. In this embodiment, the illustrated distance D between the chamber ceiling 35 of the upper member 20 and the processing surface 301 of the substrate 300 can be maintained from the maximum height at which the lift pins 60 can hold the substrate 300 to the minimum height at which the lift pins 60 can hold the substrate 300.

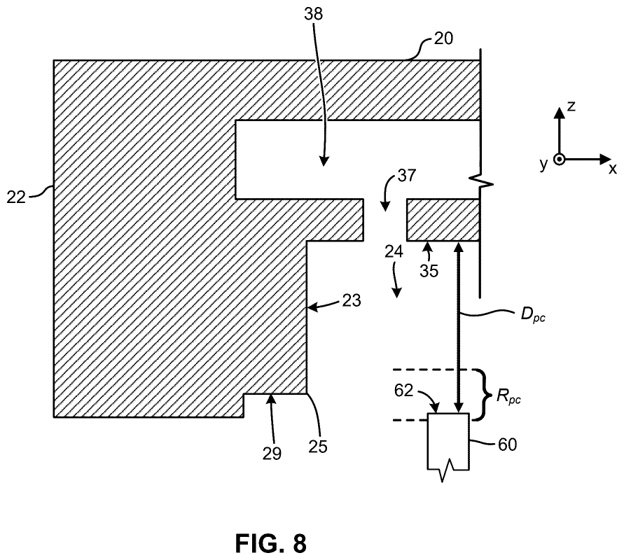

As the upper member 20 and the lift pins 60 (which hold the substrate 300) move in synchronization, the distance between the chamber ceiling 35 and the support surfaces 62 of the lift pins 60, which are the surfaces that hold the substrate 300, may be unchanged or may be maintained within a specified range. For example, FIG. 8 illustrates an example of the distance D_{pc} between the chamber ceiling 35 of the upper member 20 and the support surface 62 of a lift pin 60. While the upper member 20 and the lift pin 60 move, the distance D_{pc} may be unchanged or may be maintained within a specified range R_{pc}.

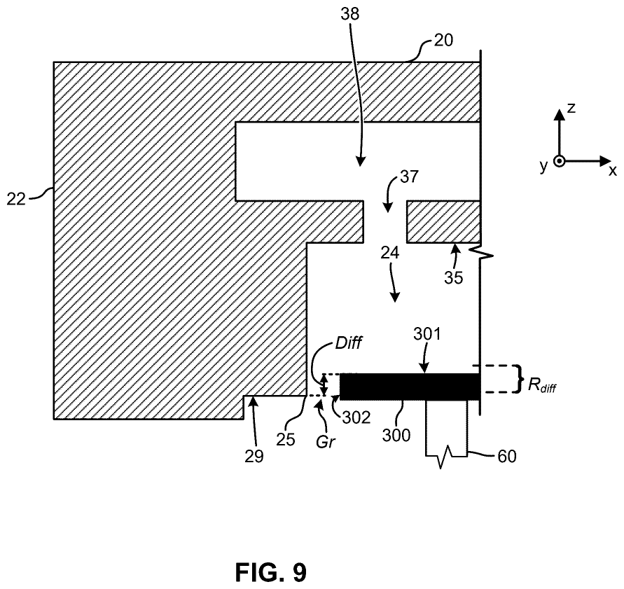

The range R_{pc} may be based on the thickness of the substrate 300. For example, the range R_{pc} may be specified such that a distance between the processing surface 301 of the substrate 300 and the chamber ceiling 35 is maintained in a specified range or that a specified z-axis difference (height difference) between the processing surface 301 of the substrate 300 and the outer limit 25 of the recessed region 24 is maintained in a specified range. For example, FIG. 9 illustrates an example of the height difference Diff between the processing surface 301 of a substrate 300 and the outer limit 25 of the recessed region 24. The height difference Diff may be maintained such that the processing surface 301 is maintained within the recessed region 24 (e.g., as shown in FIG. 9, such that the z-axis coordinate of the processing surface 301 is greater than the z-axis coordinate of the outer limit 25).

Using the height of the substrate 300, the specified range R_{pc} of the distance D_{pc} between the chamber ceiling 35 of the upper member 20 and the support surface 62 of a lift pin 60 may be specified such that the height difference Diff between the processing surface 301 of the substrate 300 and the outer limit 25 of the recessed region 24 is maintained within a specified range, for example, the range Raiff of the height difference Diff that is shown in FIG. 9.

Furthermore, using the height of the substrate 300, the specified range R_{pc} of the distance D_{pc} between the chamber ceiling 35 of the upper member 20 and the support surface 62 of a lift pin 60 may be specified such that the distance D between the chamber ceiling 35 of the upper member 20 and the processing surface 301 of the substrate 300 is maintained within a specified range.

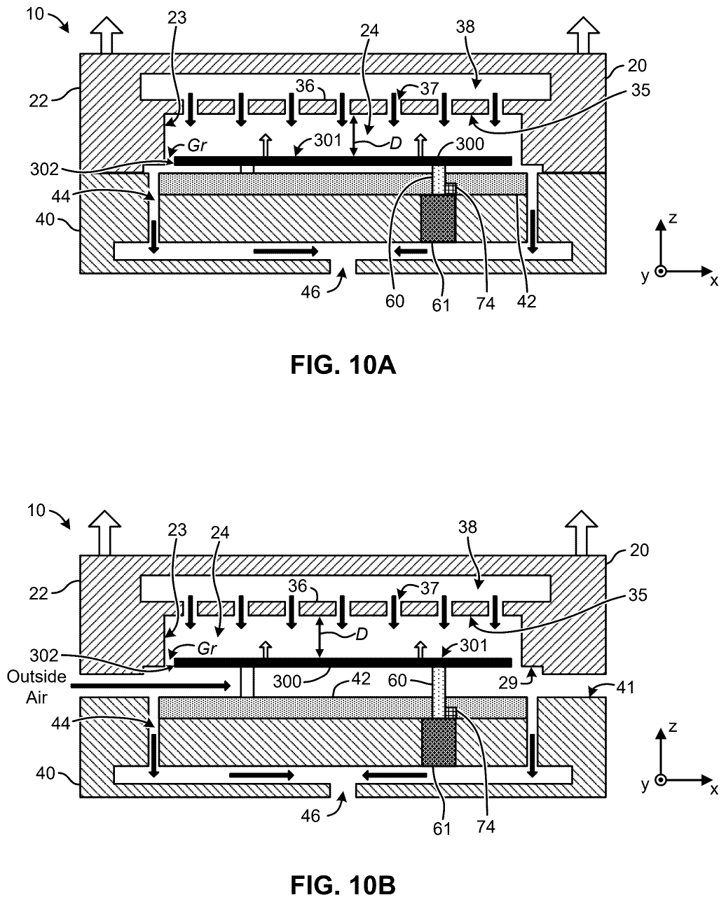

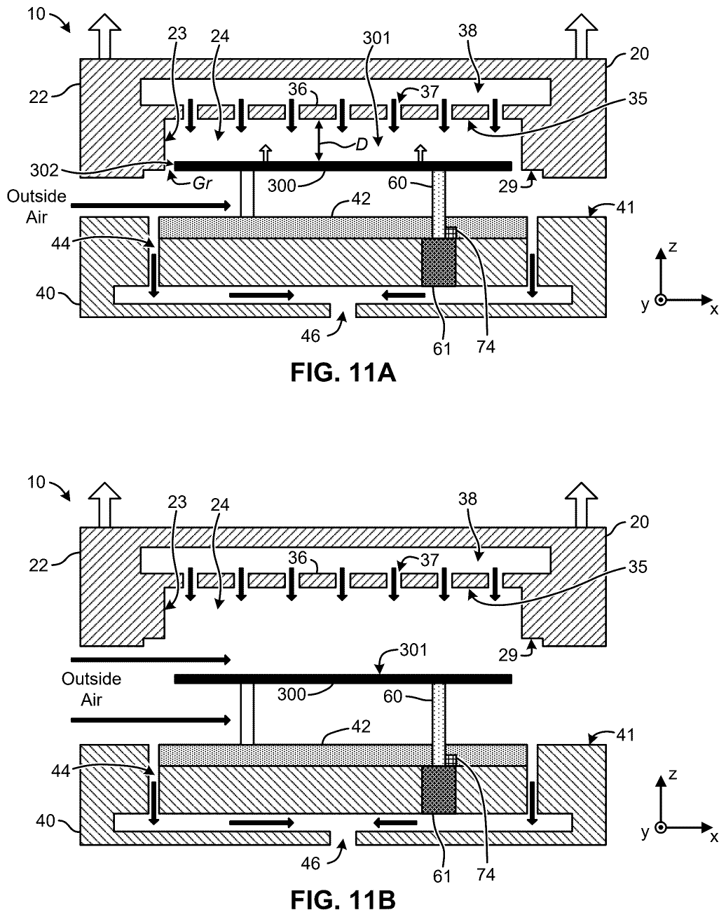

Also for example, FIGS. 10A, 10B, 11A, and 11B illustrate an example embodiment of an upper member 20 and a substrate 300 that are moved relative to a lower member 40 while maintaining a micro environment between the processing surface 301 and the chamber ceiling 35.

In FIG. 10A, the upper member 20 is in contact with the lower member 40, and there is a narrow gap Gr between the outer edge 302 of the upper member 20 and the lower member 40. In some embodiments, this is the closed position of the chamber 10. A substrate 300 is held by the lift pins 60, and the lift pins 60 hold the substrate 300 near the heating plate 42. Also, a purge gas flows through the openings 37 of the distributor 36, and any gas in the chamber 10 may be drawn in to the vent 44.

In FIG. 10A, the opening of the chamber 10 is starting, for example because a baking process is complete. The chamber actuators 11 begin to lift the upper member 20, and the lift pins 60 begin to lift the substrate 300 in synchronization with the movement of the upper member 20. Because of the baking process, the substrate 300 is hot.

In some embodiments, before the chamber actuators 11 begin to lift the upper member 20, the lift pins 60 first move the substrate 300 to a position where the distance D between the chamber ceiling 35 of the upper member 20 and the processing surface 301 of the substrate 300 is a specified distance or is within a specified range. Once the distance D between the chamber ceiling 35 of the upper member 20 and the processing surface 301 of the substrate 300 is the specified distance or is within the specified range, the chamber actuators 20 and the lift pins 60 then move the upper member 20 and the substrate 300 in synchronization.

In FIG. 10B, the upper member 20 and the substrate 300 have been moved away from the lower member 40. At least part of the substrate 300 remains positioned in the recessed region 24, and consequently the outer edge 302 of the substrate 300 and the chamber sidewalls 23 of the upper member 20 maintain the narrow gap Gr therebetween as the upper member 20 and the substrate 300 move. The lift-pin actuators 61 move the lift pins 60 to raise the substrate 300 in synchronization with the movement of the upper member 20 such that the distance D between the chamber ceiling 35 of the upper member 20 and the processing surface 301 of the substrate 300 is maintained at a specified distance or within a specified range. The vent 44 continues to draw in any gas in the chamber 10.

Because the upper member 20 has been separated from the lower member 40, outside air flows in to the chamber 10. The outside air can flow between the substrate 300 and the heating plate 42, and this flow cools the substrate 300. However, the purge gas continues to flow through the openings 37 and out the vent 44 (and out of the space between the upper member 20 and the lower member 40). Because of the flow of the purge gas and the narrow gap Gr between the outer edge 302 of the substrate 300 and the chamber sidewalls 23, the flow of the outside air over the processing surface 301 is restricted (e.g., prevented, maintained below a specified level). The restriction of the flow of the outside air over the processing surface 301 maintains a lower concentration of oxygen in the micro environment between the chamber ceiling 35 of the upper member 20 and the processing surface 301 of the substrate 300 as the upper member 20 and the substrate 300 move away from the lower member 40. But, because the cooler outside air can flow under the substrate 300, the substrate 300 cools more rapidly.

Also, synchronizing the movement of the substrate 300 and the movement of the upper member 20 prevents a piston action that sucks the outside air into the space between the chamber ceiling 35 of the upper member 20 and the processing surface 301 of the substrate 300.

In FIG. 11A, the upper member 20 and the substrate 300 have been moved farther away from the lower member 40. At least part of the substrate 300 is still positioned in the recessed region 24, and consequently the outer edge 302 of the substrate 300 and the chamber sidewalls 23 of the upper member 20 continue to maintain the narrow gap Gr therebetween. The vent 44 continues to draw in any gas in the chamber 10.

More outside air can flow between the substrate 300 and the heating plate 42, and this flow further cools the substrate 300. Also, the purge gas continues to flow through the openings 37. Because of the flow of the purge gas and the narrow gap Gr between the outer edge 302 of the substrate 300 and the chamber sidewalls 23, the flow of the outside air over the processing surface 301 remains restricted, and the lower concentration of oxygen in the micro environment between the chamber ceiling 35 of the upper member 20 and the processing surface 301 of the substrate 300 is maintained.

However, in FIG. 11A, the lifts pins 60 have reached an unloading height, which might be their maximum height. Thus, after reaching the position shown in FIG. 11A, the substrate 300 is not moved farther away from the lower member 40. In some embodiments, the movement of the upper member 20 is paused in this position to allow the substrate 300 to cool further while the lower concentration of oxygen in the micro environment between the chamber ceiling 35 of the upper member 20 and the processing surface 301 of the substrate 300 is maintained.

In FIG. 11B, the upper member 20 has moved further away from both the substrate 300 and the lower member 40. Consequently, the narrow gap Gr between the outer edge 302 of the substrate 300 and the chamber sidewalls 23 no longer exists, and outside air can also flow over the processing surface 301 of the substrate 300.

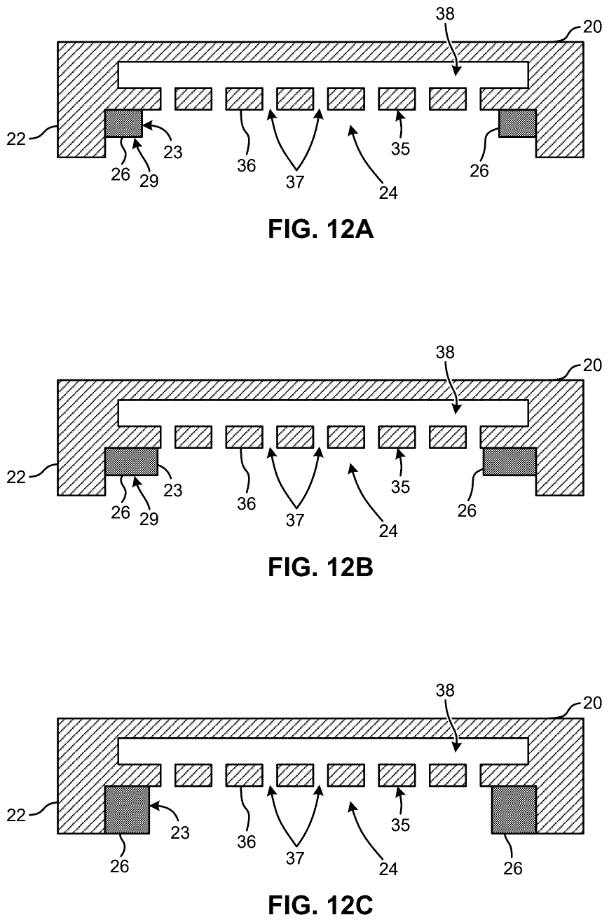

FIG. 12A illustrates an example embodiment of an upper member 20. The upper member 20 includes a removable liner 26, which forms the chamber sidewalls 23 and which is not formed as an integral part of the walls 22. The removable liner 26 can be removed and replaced with another removable liner of a different size to change the dimensions of the recessed region 24 in the x-y plane (e.g., to change a diameter, a width, or a length of the recessed region). The removable liner 26 that is installed in the upper member 20 may be selected based on the dimensions of a substrate 300, for example to produce a specified narrow gap Gr between the outer edge 302 of the substrate 300 and the chamber sidewall 23 when the substrate 300 is positioned in the recessed region 24. The removable liner 26 may also be selected based on both the dimensions of the substrate 300 and the positioning accuracy of the robotic substrate handler 90.

FIG. 12B illustrates an example embodiment of an upper member 20. The removable liner 26 in FIG. 12B is different from the removable liner 26 in FIG. 12A. The removable liner 26 in FIG. 12B has a smaller diameter than the removable liner 26 in FIG. 12A.

FIG. 12C illustrates an example embodiment of an upper member 20. The removable liner 26 in FIG. 12C is different from the removable liners 26 in FIGS. 12A and 12B. The removable liner 26 in FIG. 12C has a smaller diameter than the removable liner 26 in FIG. 12A and a larger diameter than the removable liner 26 in FIG. 12B. Also, along the z-axis, the removable liner 26 extends to the bottom of the wall 22, and thus the upper member 20 does not include the plateau 29.

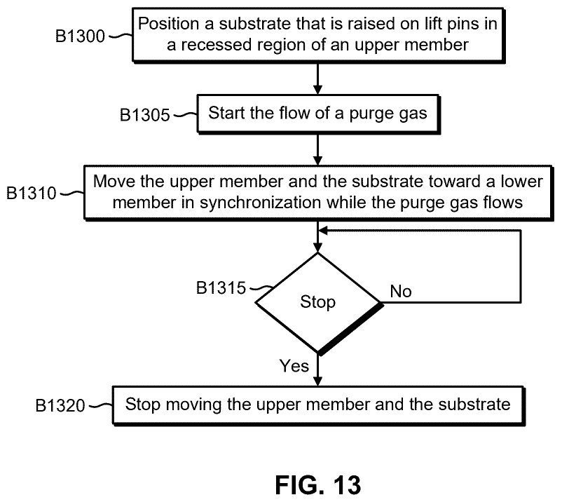

FIG. 13 illustrates an example embodiment of an operational flow for processing a substrate. Although this operational flow and the other operational flows that are described herein are each presented in a certain respective order, some embodiments of these operational flows perform at least some of the operations in different orders than the presented orders. Examples of different orders include concurrent, parallel, overlapping, reordered, simultaneous, incremental, and interleaved orders. Also, some embodiments of these operational flows include operations (e.g., blocks) from more than one of the operational flows that are described herein. Thus, some embodiments of the operational flows may omit blocks, add blocks (e.g., include blocks from other operational flows that are described herein), change the order of the blocks, combine blocks, or divide blocks into more blocks relative to the example embodiments of the operational flows that are described herein.

This operational flow and the other operational flows that are described herein are performed by a substrate-processing system 5 (e.g., as shown in FIG. 1) or a thermal-process chamber 10 that is controlled by a control device 150. In some embodiments, the members of the substrate-processing system 10 are controlled by two or more control devices 150 or by one or more other specially-configured computing devices.

The flow starts in B1300, where a substrate 300 that is raised on lift pins 60 is positioned in the recessed region 24 of an upper member 20. For example, after the substrate 300 has been placed on the lift pins 60, which may be raised before or after the substrate 300 is placed thereon, one or more chamber actuators 11 may move the upper member 20 toward the substrate 300 until at least a processing surface 301 of the substrate 300 is positioned in the recessed region 24. A control device 150 may control the lift-pin actuators 61 to raise the lift pins 60, control a robotic substrate handler 90 to place the substrate 300 on the lift pins 60, and control the chamber actuators 11 to move the upper member 20 toward the substrate 300.

Next, in block B1305, the flow of a purge gas is started. For example, a gas supply 91 may be activated, or a supply-side valve 51 that allows the purge gas to flow into the upper member 20 may be opened. The control device 150 may control the gas supply 91 or the supply-side valve 51. Also, block B1305 may be performed before block B1300. In some embodiments, the control device 150 controls the gas supply 91 and the supply-side valve 51 to constantly supply the flow of the purge gas to the upper member 20 from before the substrate 300 is positioned on the lift pins 60 until after the substrate 300 is unloaded from the lift pins 60 or to constantly supply the flow of the purge gas to the upper member 20 while the thermal-process chamber 10 is in use.

Then, in block B1310, the upper member 20 and the substrate 300 are moved toward a lower member 40 while the purge gas flows (e.g., as shown in FIGS. 5B and 6A). The one or more chamber actuators 11 and the lift-pin actuators 61 move the upper member 20 and the substrate 300 in synchronization. Thus, the distance D_{pc} between the chamber ceiling 35 of the upper member 20 and the support surfaces 62 of the lifts pins 60 remains within a specified range (e.g., the specified range R_{pc} in FIG. 8) or does not change. Consequently, the distance D between the chamber ceiling 35 of the upper member 20 and the processing surface 301 of the substrate 300 does not change or is maintained within a specified range.

The control device 150 may control the lift-pin actuators 61 to move the lift pins 60 (and thus the substrate 300) and control the chamber actuators 11 to move the upper member 20 in synchronization.

When the substrate 300 is positioned in the recessed region 24, the outer edge 302 of the substrate 300 and the chamber sidewalls 23 of the upper member 20 form a narrow gap Gr therebetween. The flow of the purge gas forces other gases (e.g., oxygen) out of the space between the processing surface 301 of the substrate 300 and the chamber ceiling 35 of the upper member 20. And the narrow gap Gr between the outer edge 302 of the substrate 300 and the chamber sidewalls 23 limits or prevents the flow of outside gases through the narrow gap Gr into the space between the processing surface 301 and the chamber ceiling 35. Consequently, the concentration of oxygen in the space between the processing surface 301 and the chamber ceiling 35 decreases or remains low (e.g., does not increase) as the upper member 20 and the substrate 300 move.

In block B1315, the control device 150 determines whether to stop the movement of the upper member 20 and the substrate 300 toward the lower member 40. For example, the control device 150 may determine to stop the movement of the upper member 20 and the substrate 300 toward the lower member 40 when the upper member 20 contacts the lower member 40 or when the upper member 20 is a specified distance from the lower member 40. If the control device 150 determines not to stop the movement of the upper member 20 and the substrate 300 toward the lower member 40 (B1315=No), then the moving continues and the flow returns to block B1315. If the control device 150 determines to stop the movement of the upper member 20 and the substrate 300 toward the lower member 40 (B1315=Yes), then the flow proceeds to block B1320.

In block B1320, the moving of the upper member 20 and the substrate 300 is stopped. For example, the control device 150 may control the chamber actuators 11 and the lift-pin actuators 61 to stop moving the upper member 20 and the substrate 300.

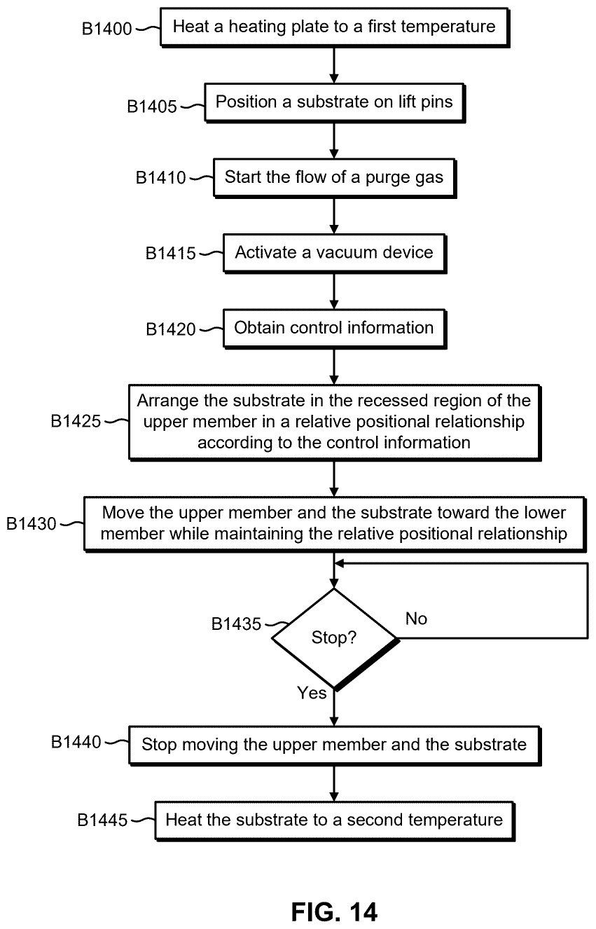

FIG. 14 illustrates an example embodiment of an operational flow for processing a substrate.

In block B1400, a control device 150 controls a heating plate 42 to heat itself to a first temperature.

Next, in block B1405, a robotic substrate handler 90, which may be controlled by the control device 150, positions a substrate 300 on lift pins 60. Before the substrate 300 is placed on the lift pins 60, the control device 150 may control the lift-pin actuators 61 to raised the lift pins 60, and thus the substrate 300 may be held away from the heating plate 42.

Then, in block B1410, the control device 150 controls a gas supply 91 to start the flow of a purge gas to the upper member 20. Block B1410 may include activating the gas supply 91 or opening a supply-side valve 51 that allows the purge gas to flow into the upper member 20. In some embodiments, the control device 150 controls the gas supply 91 and the supply-side valve 51 to constantly supply the flow of the purge gas to the upper member 20 from before the substrate 300 is positioned on the lift pins 60 until after the substrate 300 is unloaded from the lift pins 60 or to constantly supply the flow of the purge gas to the upper member 20 while the thermal-process chamber 10 is in use.

The flow then moves to block B1415, where the control device 150 activates a vacuum device 92. And block B1415 may include opening an exhaust-side valve 52. When the vacuum device 92 is active (is operating), and the exhaust-side valve 52, if included, is open, the vacuum device 92 draws gases into the vent 44 of the lower member 40. In some embodiments, the control device 150 controls the vacuum device 92 to always be active and the exhaust-side valve 52, if included, to be open while the thermal-process chamber 10 is in use.

And, in block B1420, the control device 150 obtains control information. For example, the control device 150 may obtain the control information by retrieving the control information from storage, by receiving the control information via user inputs, or by receiving the control information from another computing device (e.g., a server).

The control information includes information that indicates the positional relationship between the upper member 20 and the substrate 300 and information that indicates a temperature to which the substrate 300 or the heating plate 42 is to be heated. The control information may also indicate a maximum oxygen concentration at the processing surface 301 of the substrate 300. For example, the control information may include at least some of the following: a thickness of the substrate 300, a diameter of the substrate 300, a width of the substrate 300, a length of the substrate 300, a distance between the processing surface 301 of the substrate 300 and the chamber ceiling 35 of the upper member 20, a second temperature to which the substrate 300 (and the processing surface 301 in particular) is to be heated, a duration for which the substrate 300 is to be heated, and at least one maximum oxygen concentration at the processing surface 301 (which may include respective maximum oxygen concentrations for different temperatures).

Also, at least some of blocks B1415-B1420 may be performed before block B1400 or before block B1405. And the control information may also include the first temperature to which the heating plate 42 is to be heated.

Then, in block B1425, the control device 150 controls the chamber actuators 11 and the lift-pin actuators 61 to arrange the substrate 300 in the recessed region 24 of the upper member 20 according to a relative positional relationship indicated by the control information. When the substrate 300 is arranged in the recessed region 24 of the upper member 20 according to the relative positional relationship, the distance between the processing surface 301 of the substrate 300 and the chamber ceiling 35 of the upper member 20 is a specified distance or is within a specified range of distances, and the distance D_{pc} between the chamber ceiling 35 of the upper member 20 and the support surfaces 62 of the lifts pins 60 is a specified distance or is within a specified range of distances. Also, when the substrate 300 is arranged in the recessed region 24 of the upper member 20 according to the relative positional relationship, the outer edge 302 of the substrate 300 and the chamber sidewalls 23 of the upper member 20 form a narrow gap Gr therebetween.

Next, in block B1430, the control device 150 controls the chamber actuators 11 and the lift-pin actuators 61 to move the upper member 20 and the substrate 300 toward the lower member 40 while maintaining the relative positional relationship (e.g., as shown in FIGS. 5B and 6A).

The narrow gap Gr between the outer edge 302 of the substrate 300 and the chamber sidewalls 23 and the flow of the purge gas cause the concentration of oxygen in the space between the processing surface 301 and the chamber ceiling 35 to decrease as the upper member 20 and the substrate 300 move.

In block B1435, the control device 150 determines whether to stop the movement of the upper member 20 and the substrate 300 toward the lower member 40 (e.g., as described in block B1315). If the control device 150 determines not to stop the movement of the upper member 20 and the substrate 300 toward the lower member 40 (B1315=No), then the moving continues and the flow returns to block B1435. If the control device 150 determines to stop the movement of the upper member 20 and the substrate 300 toward the lower member 40 (B1435=Yes), then the flow proceeds to block B1440.

In block B1440, the control device 150 controls the chamber actuators 11 and the lift-pin actuators 61 to stop moving the upper member 20 and the substrate 300. In some embodiments, after the chamber 10 is closed, the control device 150 controls the lift-pin actuators 61 to further lower the substrate 300, such that the distance between the processing surface 301 of the substrate 300 and the chamber ceiling 35 of the upper member 20 is not the specified distance or is not within the specified range of distances, and such that the distance D_{pc} between the chamber ceiling 35 of the upper member 20 and the support surfaces 62 of the lifts pins 60 is not the specified distance or is not within the specified range of distances.

Finally, in block B1445, the control device 150 controls the chamber 10 to heat the substrate 300 to the second temperature, which is included in the control information, or to heat the substrate 300 for a duration (period of time) that is included in the control information.

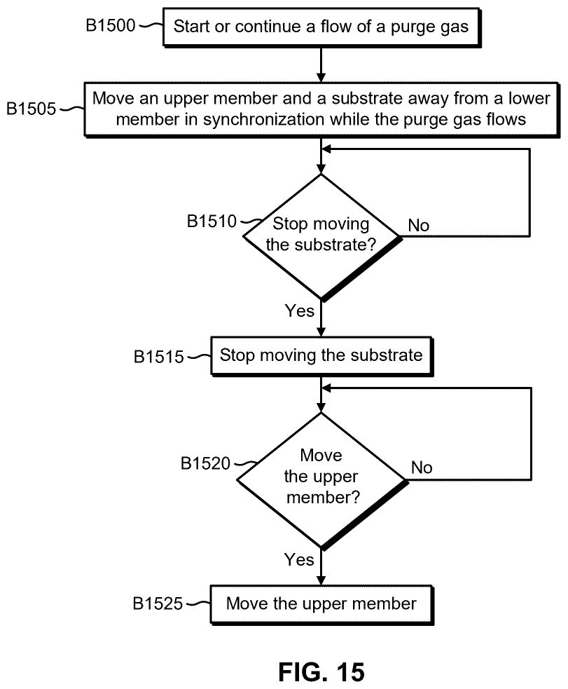

FIG. 15 illustrates an example embodiment of an operational flow for processing a substrate.

In block B1500, the flow of a purge gas is started or, if the purge gas is already flowing, the flow of the purge gas is continued.

Next, in block B1505, the upper member 20 and the substrate 300 are moved away from the lower member 40 while the purge gas flows (e.g., as shown in FIGS. 10B and 11A). The one or more chamber actuators 11, the lift-pin actuators 61, and the lift pins 60 move the upper member 20 and the substrate 300 in synchronization. Thus, the distance D between the chamber ceiling 35 of the upper member 20 and the processing surface 301 of the substrate 300 does not change or is maintained within a specified range (and the distance D_{pc} between the chamber ceiling 35 of the upper member 20 and the support surfaces 62 of the lifts pins 60 remains within a specified range or does not change). The control device 150 may control the lift-pin actuators 61 to move the lift pins 60 (and thus the substrate 300) and control the chamber actuators 11 to move the upper member 20 in synchronization.

And before the one or more chamber actuators 11 and the lift-pin actuators 61 move the upper member 20 and the substrate 300 in synchronization, the lift-pin actuators 61 may move the substrate 300 to a position where the distance D between the chamber ceiling 35 of the upper member 20 and the processing surface 301 of the substrate 300 is a distance that is to be maintained or is within the specified range (and the distance D_{pc} between the chamber ceiling 35 of the upper member 20 and the support surfaces 62 of the lifts pins 60 is a distance that is to be maintained or is within the specified range).

As described above, when the substrate 300 is positioned in the recessed region 24, the outer edge 302 of the substrate 300 and the chamber sidewalls 23 of the upper member 20 form a narrow gap Gr therebetween. The flow of the purge gas forces other gases (e.g., oxygen) out of the space between the processing surface 301 of the substrate 300 and the chamber ceiling 35 of the upper member 20. And the narrow gap Gr between the outer edge 302 of the substrate 300 and the chamber sidewalls 23 limits or prevents the flow of outside gases through the narrow gap Gr into the space between the processing surface 301 and the chamber ceiling 35. Consequently, the concentration of oxygen in the space between the processing surface 301 and the chamber ceiling 35 decreases, does not increase, or remains low as the upper member 20 and the substrate 300 move.

Then, in block B1510, the control device 150 determines whether to stop the movement of the substrate 300 away from the lower member 40. For example, the control device 150 may determine to stop the movement of the substrate 300 away from the lower member 40 when the substrate 300 is a specified distance from the lower member 40, such as a particular part of the lower member 40 (e.g., the heating plate 42).

If the control device 150 determines not to stop the movement of the substrate 300 away from the lower member 40 (B1510=No), then the moving continues and the flow returns to block B1510. If the control device 150 determines to stop the movement of the substrate 300 away from the lower member 40 (B1510=Yes), then the flow proceeds to block B1515.

In block B1515, the movement of the substrate 300 is stopped. For example, the control device 150 may control the lift-pin actuators 61 to stop moving the lift pins 60 that hold the substrate 300. Also, the movement of the upper member 20 is stopped.

Next, in block B1520, the control device 150 determines whether to move the upper member 20 farther away from the lower member 40. For example, the control device 150 may determine to move the upper member 20 away from the lower member 40 when the temperature of the substrate 300 has cooled to a specified temperature or when a specified time has elapsed.

If the control device 150 determines to not move the upper member 20 farther away from the lower member 40 (B1520=No), then the flow returns to block B1520, and the upper member 20 remains stopped. If the control device 150 determines to move the upper member 20 farther away from the lower member 40 (B1520=Yes), then the flow proceeds to block B1525.

In block B1525, the upper member 20 is moved farther away from the lower member 40. For example, the control device 150 may control the chamber actuators 11 to move the upper member 20 to a specified distance from the lower member 40.

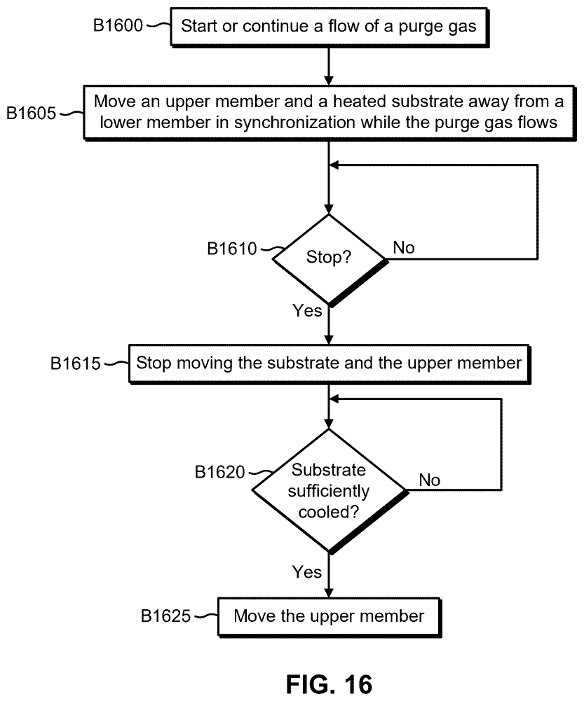

FIG. 16 illustrates an example embodiment of an operational flow for processing a substrate.

In block B1600, the flow of a purge gas is started or, if the purge gas is already flowing, the flow of the purge gas is continued.

Next, in block B1605, the upper member 20 and a heated substrate 300 are moved in synchronization away from the lower member 40 while the purge gas flows (e.g., as shown in FIGS. 10B and 11A), for example as described in B1505 in FIG. 15. The substrate 300 may have been heated to a specified temperature or for a specified duration in the chamber 10. When block B1605 begins, the chamber 10 may be closed, the substrate 300 may be heated (e.g., to a specified temperature), and the substrate 300 may be positioned in the recessed region 24 of the upper member 20. For example, before block B1605, the lift-pin actuators 61 may have moved the substrate 300 to a position where the distance D between the chamber ceiling 35 of the upper member 20 and the processing surface 301 of the substrate 300 is a distance that is to be maintained or is within a specified range (and the distance D_{pc} between the chamber ceiling 35 of the upper member 20 and the support surfaces 62 of the lifts pins 60 is a distance that is to be maintained or is within a specified range).

Then, in block B1610, the control device 150 determines whether to stop moving the substrate 300 and the upper member 20 away from the lower member 40, for example as described in block B1510 in FIG. 15.

If the control device 150 determines not to stop moving the substrate 300 and the upper member 20 away from the lower member 40 (B1610=No), then the moving continues and the flow returns to block B1610. If the control device 150 determines to stop moving the substrate 300 and the upper member 20 away from the lower member 40 (B1610=Yes), then the flow proceeds to block B1615.

In block B1615, the moving of the substrate 300 and the upper member 40 is stopped. For example, the control device 150 may control the lift-pin actuators 61 to stop moving the lift pins 60 that hold the substrate 300 and control the chamber actuators 11 to stop moving the upper member 20.

Furthermore, the substrate 300 may be positioned in the recessed region 24 during blocks B1600 to B1620 (e.g., as shown in FIGS. 10B and 11A). For example, the upper member 20 and the substrate 300 may be stopped in the positions that are shown in FIG. 11A. And, because of the flow of the purge gas and the narrow gap Gr between the outer edge 302 of the substrate 300 and the chamber sidewalls 23, the concentration of oxygen in the space between the processing surface 301 and the chamber ceiling 35 does not increase or remains low (e.g., increases only slightly) while the upper member 20 and the substrate 300 move (in blocks B1605-B1610) and are stopped (in blocks B1615 and B1620). Thus, in blocks B1615-B1620, cooler outside air can flow into the chamber 10 and under the substrate 300, which cools the substrate 300 more quickly, while the concentration of oxygen in the space between the processing surface 301 and the chamber ceiling 35 does not increase or remains low.

In block B1620, the control device 150 determines whether the substrate 300 has sufficiently cooled. For example, the control device 150 may determine that the substrate 300 has sufficiently cooled when the temperature of the substrate 300 (or a particular part of the substrate 300) has cooled to a specified temperature or when a specified duration has elapsed.

If the control device 150 determines that substrate 300 has not sufficiently cooled (B1620=No), then the substrate 300 and the upper member 20 remain stationary, and the flow returns to block B1620. Accordingly, the substrate 300 may cool more quickly than the substrate 300 would cool in a closed chamber 10, and thermal shrinkage of the substrate 300 may also be reduced due to the low concentration of oxygen near the processing surface 301.

If the control device 150 determines that substrate 300 has sufficiently cooled (B1620=Yes), then the flow proceeds to block B1625.

In block B1625, the upper member 20 moves away from the substrate 300 and the lower member 40. For example, the control device 150 may control the chamber actuators 11 to move the upper member 20 away from the substrate 300 and the lower member (e.g., to the position shown in FIG. 11B). And the movement may be stopped when the upper member 20 reaches a specified position.

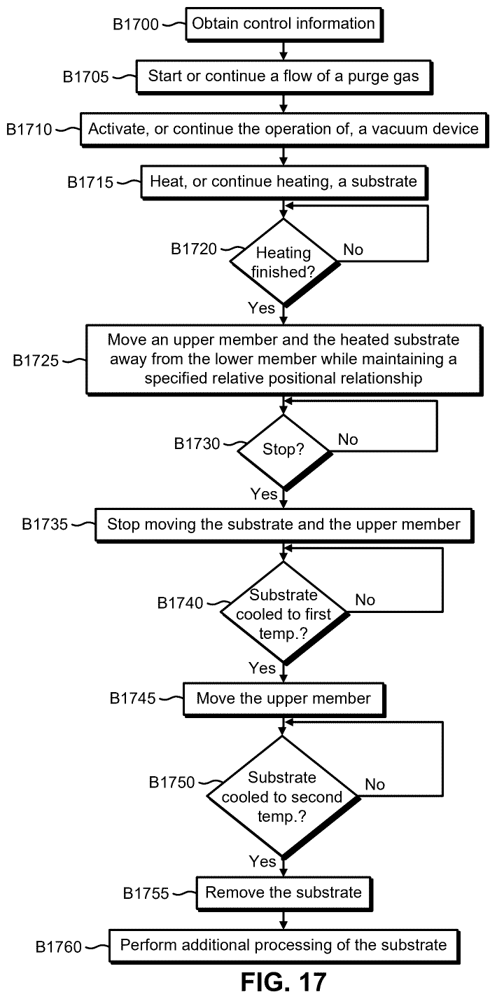

FIG. 17 illustrates an example embodiment of an operational flow for processing a substrate. In block B1700, a control device 150 obtains control information, for example as described in block B1420 in FIG. 14. The control information includes a specified relative positional relationship.

Also, before the control device performs block B1705, a substrate 300 is positioned in a closed chamber 10.

Next, in block B1705, the control device 150 controls the start of the flow of a purge gas (e.g., by activating a gas supply) to the chamber 10 or, if the purge gas is already flowing, controls the purge gas to continue flowing to the chamber 10.

Then, in block B1710, the control device 150 activates a vacuum device 92 or continues the operation of a vacuum device 92 that is already operating. When the vacuum device 92 is active (is operating), the vacuum device 92 draws gases into the vent 44 of the lower member 40.

And, in block B1715, the control device 150 controls the heating plate 42 to begin or continue heating a substrate 300. This may include increasing the temperature of the substrate 300 or maintaining the current temperature of the substrate 300 (e.g., when the current temperature is a specified temperature or within a specified temperature range).

The flow then moves to block B1720, where the control device 150 determines whether the heating of the substate 300 is finished. For example, the control device 150 may determine that the heating of the substrate 300 is finished when the temperature of the substrate 300 has reached a specified temperature of when the substrate 30 has been heated for a specified duration. If the control device 150 determines that the heating of the substate 300 is not finished (B1720=No), then the control device 150 controls the chamber 10 to continue heating the substrate 300. If the control device 150 determines that the heating of the substate 300 is finished (B1720=Yes), then the flow proceeds to block B1725.

Next, in block B1725, the control device 150 controls the lift-pin actuators 61 to arrange the substrate 300 in the recessed region 24 of the upper member 20 according to the specified relative positional relationship if the substrate 300 is not already arranged in the recessed region 24 according to the specified relative positional relationship. Consequently, the distance between the processing surface 301 of the substrate 300 and the chamber ceiling 35 of the upper member 20 is a specified distance or is within a specified range of distances. Also, when the substrate 300 is arranged in the recessed region 24 of the upper member 20 according to the relative positional relationship, the outer edge 302 of the substrate 300 and the chamber sidewalls 23 of the upper member 20 form a narrow gap Gr therebetween.

The control device 150 then controls the chamber actuators 11 and the lift-pin actuators 61 to move the upper member 20 and the substrate 300 away from the lower member 40 while maintaining the specified relative positional relationship (e.g., as shown in FIGS. 10B and 11A). Thus, the distance D between the chamber ceiling 35 of the upper member 20 and the processing surface 301 of the substrate 300 does not change or is maintained within a specified range (and the distance D_{pc} between the chamber ceiling 35 of the upper member 20 and the support surfaces 62 of the lifts pins 60 remains within a specified range or does not change). The narrow gap Gr between the outer edge 302 of the substrate 300 and the chamber sidewalls 23, the flow of the purge gas, and the flow of gas through the vent 44 cause the concentration of oxygen in the space between the processing surface 301 and the chamber ceiling 35 to not increase or to remain low as the upper member 20 and the substrate 300 move.

Then, in block B1730, the control device 150 determines whether to stop the movement of the substrate 300 and the upper member 40 away from the lower member 40, for example as described in block B1510 in FIG. 15. If the control device 150 determines not to stop the movement of the substrate 300 and the upper member 20 away from the lower member 40 (B1730=No), then the moving continues and the flow returns to block B1730. If the control device 150 determines to stop the movement of the substrate 300 and the upper member 20 away from the lower member 40 (B1730=Yes), then the flow proceeds to block B1735.

In block B1735, the control device 150 controls the chamber actuators 11 and the lift-pin actuators 61 to stop moving the upper member 20 and the substrate 300. Because the chamber 10 is open, the substrate 300 may cool more quickly. And thermal shrinkage of the substrate 300 may also be reduced due to the low concentration of oxygen near the processing surface 301 that is caused by the flow of the purge gas and the narrow gap Gr.

Next, in block B1740, the control device 150 determines whether the substrate 300 has cooled to a first temperature. If the control device 150 determines that substrate 300 has not cooled to the first temperature (B1740=No), then the substrate 300 and the upper member 20 remain stationary, and the flow returns to block B1740. If the control device 150 determines that substrate 300 has cooled to the first temperature (B1740=Yes), then the flow proceeds to block B1745.

In block B1745, the control device 150 controls the chamber actuators 11 to move the upper member 20 away from the substrate 300 and the lower member (e.g., to the position shown in FIG. 11B). And the control device 150 may control the chamber actuators 11 to stop the movement of the upper member 20 when the upper member 20 reaches a specified position.

Then, in block B1750, the control device 150 determines whether the substrate 300 has cooled to a second temperature that is lower than the first temperature. If the control device 150 determines that substrate 300 has not cooled to the second temperature (B1750=No), then the flow returns to block B1750 and the substrate 300 continues to cool while resting on the lift pins 60. If the control device 150 determines that substrate 300 has cooled to the second temperature (B1750=Yes), then the flow proceeds to block B1755.

In block B1755, the control device 150 causes a robotic substrate handler 90 to remove the substrate 300 from the chamber 10. And, in block B1760, the control device 150 controls other components of a substrate processing system to perform additional processing on the substrate 300. For example, some embodiments of block B1760 include processing the substrate 300 to manufacture a plurality of articles.

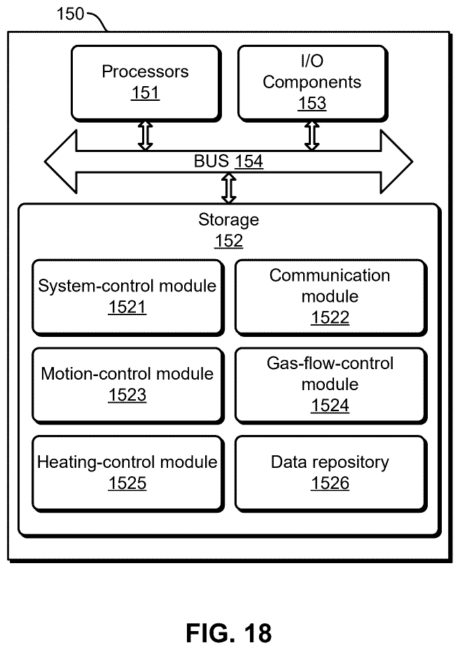

FIG. 18 is a schematic illustration of an example embodiment of a control device 150. The control device 150 includes one or more processors 151, one or more computer-readable storage media 152, one or more I/O components 153, and a bus 154.

The one or more processors 151 are or include one or more central processing units (CPUs), such as microprocessors (e.g., a single core microprocessor, a multi-core microprocessor); one or more graphics processing units (GPUs); one or more application-specific integrated circuits (ASICs); one or more field-programmable-gate arrays (FPGAs); one or more digital signal processors (DSPs); or other electronic circuitry (e.g., other integrated circuits). Furthermore, a processor 151 may be a purpose-built controller or may be a general-purpose controller. The one or more processors 151 may include a plurality of processors that include processors that are both (i) included in the control device 150 and (ii) in communication with the bonding system 100 but not included in the control device 150. And the one or more processors 151 are an example of a processing unit.

The one or more processors 151 may operate based on computer-readable instructions (e.g., in one or more programs) stored on one or more computer-readable storage media 152. As used herein, a computer-readable storage medium 152 is a computer-readable medium that includes an article of manufacture, for example a magnetic disk (e.g., a floppy disk, a hard disk), an optical disc (e.g., a CD, a DVD, a Blu-ray), a magneto-optical disk, magnetic tape, and semiconductor memory (e.g., a non-volatile memory card, flash memory, a solid-state drive, SRAM, DRAM, EPROM, EEPROM). And examples of the one or more computer-readable storage media 152 include networked-attached storage (NAS) devices, intranet-connected storage devices, and internet-connected storage devices. The one or more computer-readable storage media 152, which may include both ROM and RAM, can store computer-readable data or computer-executable instructions. Furthermore, in embodiments where the one or more computer-readable storage media 152 include RAM, the one or more processors 151 can use the RAM as a work area. Additionally, when the control device 150 or the one or more processors 151 are described as obtaining information or data, recording information or data, generating information or data, storing information or data, operating on information or data, processing information or data, etc., the information or data are stored in the one or more computer-readable storage media 152. Also, the one or more computer-readable storage media 152 are an example of a storage unit. And the computer-readable storage media 152 may be distributed among multiple processors 151.

The control device 150 also includes I/O components 153. The I/O components 153 include physical interfaces and communication components (e.g., a GPU, a network-interface controller) that enable communication (wired or wireless) with other members of the substrate-processing system 5 (e.g., a thermal-process chamber 10, chamber actuators 11, lift-pin actuators 61, a robotic substrate handler 90, a gas supply 91, a vacuum device 92, a supply-side valve 51, an exhaust-side valve 52), with other computing devices (e.g., a networked computer), and with input or output devices, which may include a display device, a network device, a keyboard, a mouse, a printing device, a light pen, an optical-storage device, a scanner, a microphone, a drive, a joystick, and a control pad.

Also, the hardware components of the control device 150 communicate via one or more buses 154 or other electrical connections. Examples of buses 154 include a universal serial bus (USB), an IEEE 1394 bus, a PCI bus, an Accelerated Graphics Port (AGP) bus, a Serial AT Attachment (SATA) bus, and a Small Computer System Interface (SCSI) bus.

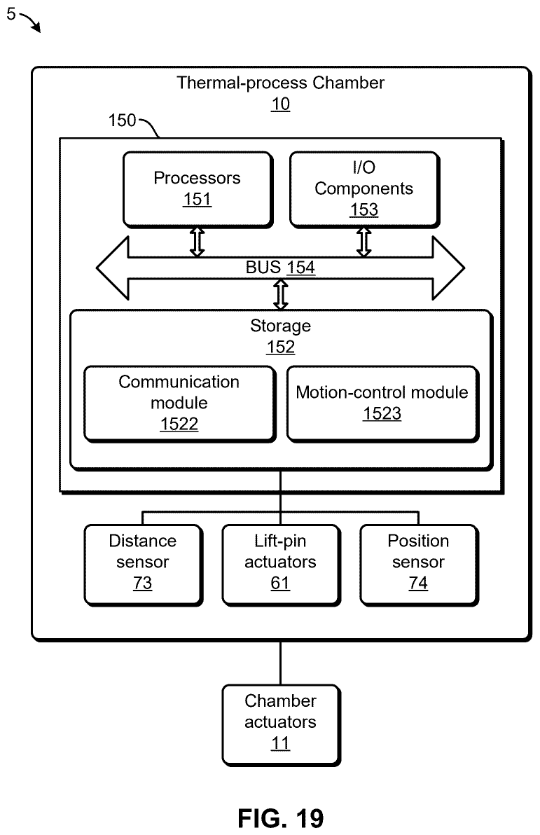

The control device 150 additionally includes a system-control module 1521, a communication module 1522, a motion-control module 1523, a gas-flow-control module 1524, and a heating-control module 1525. As used herein, the system-control module 1521, the communication module 1522, the motion-control module 1523, the gas-flow-control module 1524, and the heating-control module 1525 include logic, computer-readable data, or computer-executable instructions. In the embodiment shown in FIG. 18 (and in the embodiment shown in FIG. 19), these computing modules are implemented in software (e.g., Assembly, C, C++, C#, Java, JavaScript, BASIC, Perl, Visual Basic, Python, PHP). However, in some embodiments, these computing modules are implemented in hardware (e.g., customized circuitry) or, alternatively, a combination of software and hardware. When these computing modules are implemented, at least in part, in software, then the software can be stored in the one or more computer-readable storage media 152. Also, in some embodiments, the control device 150 includes additional or fewer such computing modules, these computing modules are combined into fewer computing modules, or these computing modules are divided into more computing modules. And each of these computing modules may use (e.g., call) other computing modules. Also, the control device 150 includes a data repository 1526, which stores information, such as control information.

The system-control module 1521 includes instructions that cause and enable the applicable components (e.g., the one or more processors 151, the storage 152, the I/O components 153) of the control device 150 to communicate with and to control the other members of a substrate-processing system 5. For example, some embodiments of the system-control module 1521 include instructions that cause the applicable components of the control device 150 to control the applicable components (e.g., the robotic substrate handler 90) of the substrate-processing system 5 to perform at least some of the operations that are described in block B1405 in FIG. 14 and in blocks B1755-B1760 in FIG. 16. The applicable components of the control device 150 operating according to the system-control module 1521 realize an example of a system-control unit.

The communication module 1522 includes instructions that cause the applicable components (e.g., the one or more processors 151, the storage 152, the I/O components 153) of the control device 150 to communicate with one or more other computing devices and with input or output devices. For example, some embodiments of the communication module 1522 include instructions that cause the applicable components of the control device 150 to perform at least some of the operations that are described in block B1420 in FIG. 14 and in block B1700 in FIG. 17. And the applicable components operating according to the communication module 1522 realize an example of a communication unit.

The motion-control module 1523 includes instructions that cause the applicable components (e.g., the one or more processors 151, the storage 152, the I/O components 153) of the control device 150 to control the components (e.g., chamber actuators 11, lift-pin actuators 61) of the substrate-processing system 5 to move and position an upper member 20 and a substrate 300. For example, some embodiments of the motion-control module 1523 include instructions that cause the applicable components of the control device 150 to control the components (e.g., chamber actuators 11, lift-pin actuators 61) of the substrate-processing system 5 to perform at least some of the operations that are described in blocks B1300 and B1310-B1320 in FIG. 13, in blocks B1425-B1440 in FIG. 14, in blocks B1505-B1525 in FIG. 15, in blocks B1605-B1615 and B1625 in FIG. 16, and in blocks B1725-B1735 and B1745 in FIG. 17. And the applicable components of the control device 150 operating according to the motion-control module 1523 realize an example of a motion-control unit.

The gas-flow-control module 1524 includes instructions that cause the applicable components (e.g., the one or more processors 151, the storage 152, the I/O components 153) of the control device 150 to control the flow of a purge gas or control the operation of a vacuum device by controlling the applicable components (e.g., a gas supply 91, a vacuum device 92, a supply-side valve 51, an exhaust-side valve 52) of the substrate-processing system 5. For example, some embodiments of the gas-flow-control module 1524 include instructions that cause the applicable components of the control device 150 to control the components (e.g., the gas supply 91, the vacuum device 92) of the substrate-processing system 5 to perform at least some of the operations that are described in block B1305 in FIG. 13, in blocks B1410-B1415 in FIG. 14, in block B1500 in FIG. 15, in block B1600 in FIG. 16, and in blocks B1705-B1710 in FIG. 17. And the applicable components of the control device 150 operating according to the gas-flow-control module 1524 realize an example of a gas-flow-control unit.

The heating-control module 1525 includes instructions that cause the applicable components (e.g., the one or more processors 151, the storage 152, the I/O components 153) of the control device 150 to control the heating and cooling of a substrate 300 by controlling the applicable components (e.g., heating plate 42) of the substrate-processing system 5. For example, some embodiments of the heating-control module 1525 include instructions that cause the applicable components of the control device 150 to control the components (e.g., heating plate 42) of the substrate-processing system 5 to perform at least some of the operations that are described in in blocks B1400 and B1445 in FIG. 14; in block B1620 in FIG. 16; and in blocks B1715-B1720, B1740, and B1750 in FIG. 17. And the applicable components of the control device 150 operating according to the heating-control module 1525 realize an example of a heating-control unit.

FIG. 19 is a schematic illustration of an example embodiment of a thermal-process chamber. The thermal-process chamber 10 includes a control device 150. The control device 150 includes one or more processors 151, one or more computer-readable storage media 152, one or more I/O components 153, a bus 154, a communication module 1522, and a motion-control module 1523. Also, the control device 150 may be implemented as a microcontroller or a system-on-a-chip (SoC).

The control device 150 controls the lift-pin actuators 61 and the chamber actuators 11, and the control device 150 also communicates with a distance sensor 73 and a position sensor 74. And the control device 150 in FIG. 19 may communicate with another control device 150 that is external to the thermal-process chamber 10.

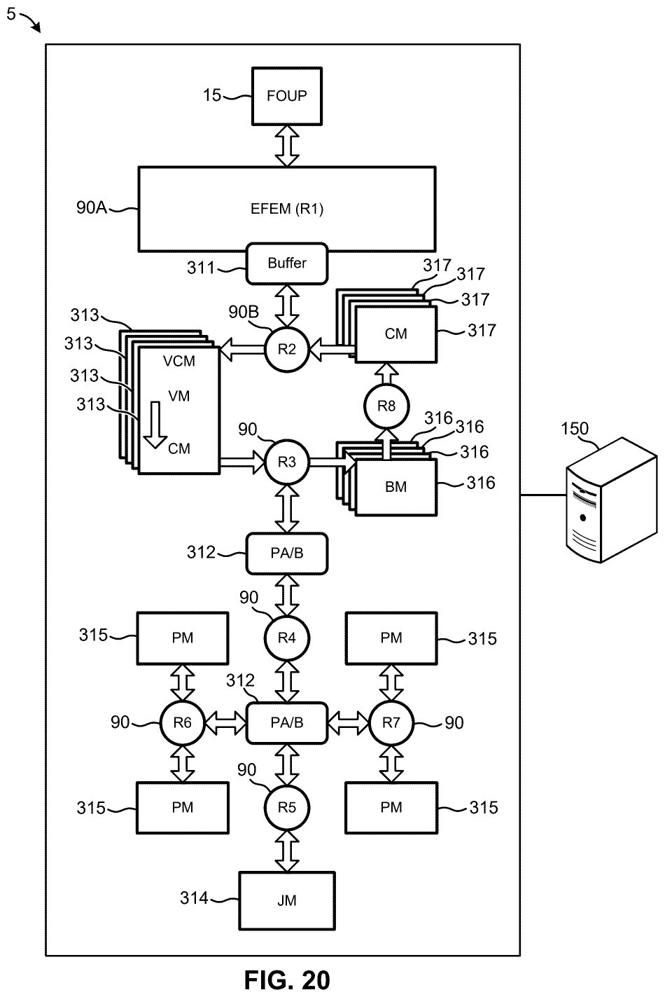

FIG. 20 is a schematic illustration of an example embodiment of a substrate-processing system 5.

The substrate-processing system 5 includes production-system machines, robotic substrate handlers 90 (robots R1, R2, R3, R4, R5, R6, R7, and R8), and at least one control device 150. Also, robotic substrate handler R1 (90A) is an equipment front-end machine (EFEM), which can load and unload substrates from a Front Opening Unified Pod (FOUP) 15.

In this embodiment, the production-system machines include the following: a buffer 311, two auto-aligner buffers (PA/Bs) 312, four vapor-cooling machines (VCMs) 313, each of which is a combination of a vapor-coating machine (VM) and a cooling machine (CM); a jetting machine (JM) 314; four planarization machines (PMs) 315; four baking machines (BM) 316, which are or which include thermal-process chambers 10; and four cooling machines (CM) 317. Each of the production-system machines can receive substrates and perform operations on the substrates. As shown in FIG. 20, the substrate-processing system 5 may have multiple production-system machines that perform the same operation.

The arrows between the production-system machines and the robotic substrate handlers 90 indicate the directions in which substrates can travel. A one-directional arrow between a robotic substrate handler 90 and a production-system machine indicates that a substrate can travel only in the direction of the arrow (i.e., the robotic substrate handler 90 can either load or, alternatively, unload the production-system machine, but not both). A bi-directional arrow between a robotic substrate handler 90 and a production-system machine indicates that a substrate can travel in either direction (i.e., the robotic substrate handler 90 can both load and unload the production-system machine). One or more of the robotic substrate handlers 90 will transfer substrates to and from FOUPs, and through a series of production-system machines.

Robotic substrate handler R1 (90A) conveys the substrates to the buffer 111, and the buffer 311 holds the substrates until robotic substrate handler R2 (90B) can unload them. Also, the buffer 311 and robotic substrate handler R1 (90A) can received completed substrates from robotic substrate handler R2 (90B), and robotic substrate handler R1 (90A) can load the completed substrates into the FOUP 15.

The two PA/Bs 312 adjust the pre-alignment states of substrates. For example, the PA/Bs 312 may align a substrate using a notch, an orientation flat, or the like formed in the substrate.

The vapor-coating machines (VMs) of the VCMs 313 apply a vapor coating to substrates. The VCMs 313 then transfer the substrates to the cooling machines (CMs), which cool the substrates. In some embodiments, the VMs are separate from the CMs, and a robotic substrate handler transfers the substrates from the VMs to the CMs. Also, in this embodiment, the VCMs 313 are arranged in a stack.

The jetting machine (JM) 314 applies drops of formable material (e.g., resist) to substrates, for example according to one or more drop patterns. Examples of the JM 314 include the dispensing systems and dispensing stations that are described in U.S. Pat. No. 11,526,076, U.S. Publication No. 2022/0315259, and U.S. Publication No. 2023/0152688, which are incorporated by reference herein for purposes of describing the JM 314.

Each planarization machine (PM) 315 performs a planarization process on a substrate. Examples of the PM 315 are described in U.S. Pat. No. 11,526,076, U.S. Publication No. 2022/0315259, and U.S. Publication No. 2023/0152688, which are incorporated by reference herein for purposes of describing the PM 315.

The baking machines (BMs) 316, which are or which include thermal-process chambers 10, bake (heat) substrates (and the BMs 316 may partially cool the substrates).

Robotic substrate handler R8 (90C) transfers the substrates from the BMs 316 to the CMs 317.

The cooling machines (CM) 317 cool the substrates.

Also, in this embodiment, the BMs 316 are arranged in a stack, and the CMs 317 are arranged in a stack.

The embodiment of a substrate-processing system 5 in FIG. 20 is an example, and some embodiments have other configurations. For example, some embodiments include different production-system machines in addition to, or in alternative to, the production-system machines shown in FIG. 20; some embodiments have different arrangements of the production-system machines; some embodiments include more or fewer robotic substrate handlers 90; some embodiments include different arrangements of robotic substrate handlers 90; and some embodiments include different types of robotic substrate handlers 90.

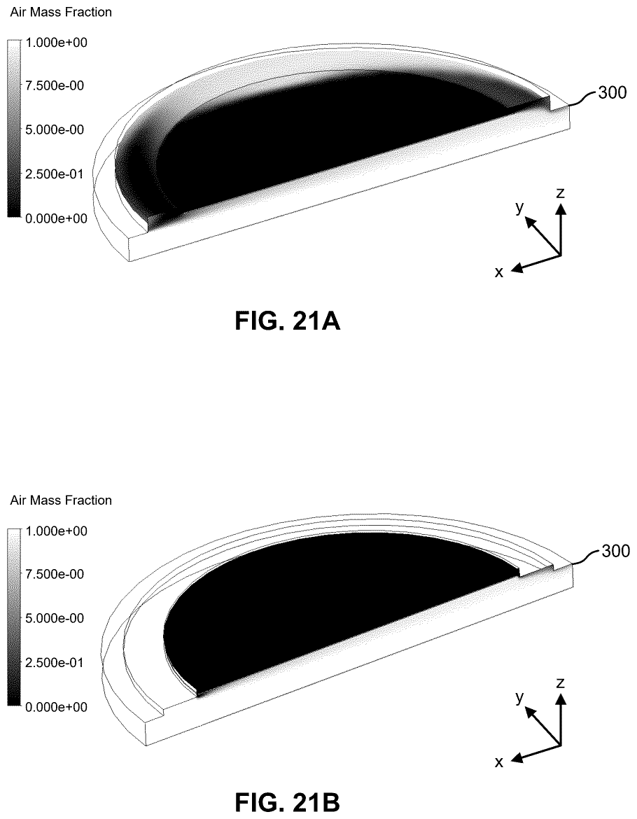

FIG. 21A illustrates the air mass fraction of a substrate. The substrate 300 in FIG. 21A is in a system that does not include the narrow gap between the outer edge 302 of the substrate 300 and the chamber sidewalls 23 of the upper member 20. FIG. 21A shows that there is a higher concentration of oxygen the surface of the substrate that is close to the edge of the substrate 300.

FIG. 21B illustrates the air mass fraction of a substrate. The substrate 300 in FIG. 21B is in a system that includes the narrow gap between the outer edge 302 of the substrate 300 and the chamber sidewalls 23 of the upper member 20. FIG. 21B shows that there is a low concentration of oxygen across the entire surface of the substrate 300.

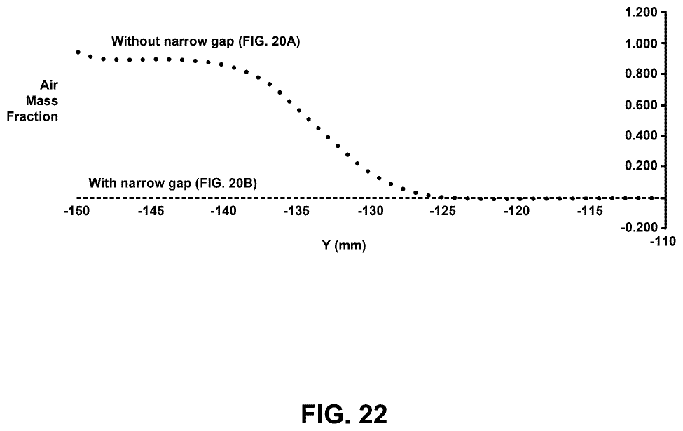

FIG. 22 is a graph that illustrates the air mass fractions of two substrates. The two substrates are the substrates in FIGS. 21A and 21B. The horizontal axis shows the distances from the centers of the substrates to their edges (each substrate has a radius of 150 mm). The vertical axis shows the air mass fraction. As shown in FIG. 22, the air mass fraction of the substrate from FIG. 21A, which is in the system that does not include the narrow gap, increases near the edge of the substrate. However, the air mass fraction of the substrate from FIG. 21B is low across the entire surface of the substrate.

At least some of the above-described devices, systems, and methods can be implemented, at least in part, by providing one or more computer-readable media that contain computer-executable instructions for realizing the above-described operations to one or more computing devices that are configured to read and execute the computer-executable instructions. The systems or devices perform the operations of the above-described embodiments when executing the computer-executable instructions. Also, an operating system on the one or more systems or devices may implement at least some of the operations of the above-described embodiments.

Furthermore, some embodiments use one or more functional units to implement the above-described devices, systems, and methods. The functional units may be implemented in only hardware (e.g., customized circuitry) or in a combination of software and hardware (e.g., a microprocessor that executes software).

In the description, specific details are set forth in order to provide a thorough understanding of the embodiments disclosed. However, well-known methods, procedures, components and circuits may not have been described in detail in order to avoid unnecessarily lengthening the present disclosure.

Also, if a member (e.g., element, part, component) is referred herein as being “on,” “against,” “connected to,” or “coupled to” another member, then the member can be directly on, against, connected or coupled to the other member, but intervening members may also be present between the member and the other member. In contrast, if a member is referred to as being “directly on,” “directly against,” “directly connected to,” or “directly coupled to” another member, then there are no intervening members present between the member and the other member.

Furthermore, the terms “comprising,” “having,” “includes,” “including,” and “containing” are to be construed as open-ended terms unless otherwise noted. Accordingly, these terms, when used in the present specification, specify the presence of described features, integers, steps, operations, elements, materials, or members, but do not preclude the presence or addition of one or more other features, integers, steps, operations, elements, materials, or members that are not explicitly described.

1. A thermal module for baking a wafer in a low oxygen environment, the thermal module comprising:
a hot plate;
a movable chamber lid having a recessed region defined by a chamber ceiling and a chamber sidewall for receiving a wafer; and
lift pins for raising or lowering the wafer above or onto the hot plate,
wherein the recessed region is configured such that, when the wafer is positioned in the recessed region, a narrow gap is formed between the wafer and the recessed region such that a low oxygen environment between the chamber ceiling and a proximal surface of the wafer can be retained.

2. The thermal module of claim 1, wherein the narrow gap is in a radial direction and is between the wafer and the chamber sidewall.

3. The thermal module of claim 1, wherein wafer includes a planarization layer and the proximal surface is a top surface of the planarization layer.

4. The thermal module of claim 1, further comprising:
a control device configured to synchronize motion of the movable chamber lid with motion of the lift pins.

5. The thermal module of claim 1,
wherein the lift pins contact a distal surface of the wafer, and
wherein the control device is configured to control the lift pins and the movable chamber lid to move in synchronization from respective first positions to respective second positions while the wafer is held in the recessed region by the lift pins and is moved in synchronization with the recessed region.

6. The thermal module of claim 1, wherein the narrow gap is 0.5 mm to 5 mm.

7. The thermal module of claim 1, wherein the movable chamber lid comprises a port that accepts an inflow of a gas and an opening that expels the gas into the recessed region.

8. A thermal module for baking a wafer in a low oxygen environment, the thermal module comprising:
a hot plate;
a movable chamber lid having a recessed region defined by a chamber ceiling and a chamber sidewall for receiving a wafer;
lift pins for raising or lowering the wafer above or onto the hot plate; and
a control device,
wherein the control device is configured to control the movable chamber lid and the lift pins to move in synchronization.

9. The thermal module of claim 8,
wherein the control device is further configured to control the lift pins and the movable chamber lid to move in synchronization from respective first positions to respective second positions while the wafer is held in the recessed region by the lift pins and is moved in synchronization with the recessed region.

10. The thermal module of claim 9,
wherein the control device is further configured to control the lift pins and the movable chamber lid to move in synchronization from the respective second positions to the respective first positions while the wafer is held in the recessed region by the lift pins and is moved in synchronization with the recessed region.

11. The thermal module of claim 8,
wherein the recessed region is configured such that, when the wafer is positioned in the recessed region, a narrow gap is formed between the wafer and the recessed region in a radial direction.

12. The thermal module of claim 11,
wherein the control device is further configured to control the lift pins and the movable chamber lid to move in synchronization from respective first positions to respective second positions while maintaining the narrow gap between the wafer and the recessed region in the radial direction.

13. The thermal module of claim 8, further comprising:
a valve,
wherein the movable chamber lid comprises a port that accepts an inflow of a gas and an opening that expels the gas into the recessed region,
wherein the valve controls a flow of the gas to the port, and
wherein the control device is further configured to control the valve to enable the flow of the gas while the movable chamber lid and the lift pins move.

14. A method comprising:
controlling lift pins to move a wafer from a first position to a second position; and
controlling a movable chamber lid to move from a third position to a fourth position, the movable chamber lid having a recessed region defined by a chamber ceiling and a chamber sidewall for receiving the wafer,
wherein the movable chamber lid and the lift pins are controlled to move in synchronization while the lift pins move the wafer from the first position to the second position and the movable chamber lid moves from the third position to the fourth position.

15. The method of claim 14, wherein the movable chamber lid and the lift pins are controlled to move such that, while the lift pins move the wafer from the first position to the second position and the movable chamber lid moves from the third position to the fourth position, a distance between the wafer and the chamber ceiling is unchanged.

16. The method of claim 14, wherein the movable chamber lid and the lift pins are controlled to move such that, while the lift pins move the wafer from the first position to the second position and the movable chamber lid moves from the third position to the fourth position, a distance between the wafer and the chamber sidewall is unchanged.

17. The method of claim 14, further comprising:
controlling gas to flow through the movable chamber lid into the recessed region while the lift pins move the wafer from the first position to the second position and the movable chamber lid moves from the third position to the fourth position.

18. The method of claim 14, further comprising:
controlling the lift pins to move the wafer from the second position to the first position; and
controlling the movable chamber lid to move from the fourth position to the second position,
wherein the movable chamber lid and the lift pins are controlled to move in synchronization while the lift pins move the wafer from the second position to the first position and the movable chamber lid moves from the fourth position to the third position.

19. The method of claim 14, further comprising:
removing the wafer from the lift pins; and
processing the wafer to manufacture a plurality of articles.

20. The method of claim 14, further comprising:
controlling the movable chamber lid to move to a fifth position;
loading the wafer onto the lift pins that are in the first position above a hot plate, while the movable chamber lid is in the fifth position;
controlling the movable chamber lid to move from the fifth position to the third position;
while the chamber lid is in the third position and the lift pins are in the first position a lower gap between a bottom of the wafer and the hot plate is a first value until gas flowing into the recessed region has created a low oxygen environment;
wherein the movable chamber lid is moved to the third position and the lift pins are moved to the second position in synchronization after the low oxygen environment is created;
holding the wafer at a prespecified soak time above the hot plate while the lift pins are in the second position and the movable chamber lid is in the third position;
controlling the movable chamber lid and the lift pins to increase the lower gap while maintaining a low oxygen environment until a proximal surface of the wafer reaches a threshold temperature;
controlling the movable chamber lid to move to a fifth position; and
removing the wafer from the lift pins.
